(19) United States
(12) Patent Application Publication
(10) Pub. No.: US 2019/0324064 A1
(43) Pub. Date: Oct. 24, 2019

(54) REDUCED COST RATIO METRIC MEASUREMENT TECHNIQUE FOR TARIFF METERING AND ELECTRICAL BRANCH CIRCUIT PROTECTION

(71) Applicant: James J. Kinsella, Pleasant View, TN (US)

(72) Inventor: James J. Kinsella, Pleasant View, TN (US)

(21) Appl. No.: 16/503,574

(22) Filed: Jul. 4, 2019

Related U.S. Application Data
(63) Continuation-in-part of application No. 14/037,922, filed on Sep. 26, 2013, now abandoned.

(51) Int. Cl. G01R 19/00; G01R 1/20; G01R 27/02; G01R 35/00

(52) U.S. Cl. CPC G01R 19/0092; G01R 35/005; G01R 27/02; G01R 1/203

(57) ABSTRACT

A ratio metric (RM) approach to providing the current sensing function of service currents to smart metering applications results in an RM current sensor assembly and RM differential current sensor assembly that can replace prior art sensors currently used for this purpose, with substantial reduction in cost of operation and size. The current sensor assemblies leverage current dividers having estimated current ratios, with any error being calibrated out of the sensor assembly by various approaches, such as requiring a single parametric adjustment of a burden resistor value to establish an expected output magnitude for a known current input magnitude to a requisite degree of accuracy. Calibration profiles for the entire service current range can be generated and used with the current sensor assemblies. Multiple RM current sensor assemblies can be used for segments of the current range to further increase accuracy. Improved and low cost leakage current protection is provided.

### CROSS-REFERENCE TO RELATED APPLICATIONS

This application claims priority as a continuation-in-part of U.S. application Ser. No. 14/037,922, filed Sep. 26, 2013 and titled “RATIO METRIC CURRENT MEASUREMENT,” and which is hereby incorporated herein in its entirety by this reference.

This Application is related to U.S. patent application Ser. No. ______, titled “MONITORING SERVICE CURRENT FOR ARC FAULT DETECTION IN ELECTRIC BRANCH CIRCUITS,” filed concurrently herewith, and which is incorporated herein in its entirety by this reference.

### FIELD OF THE INVENTION

The invention generally relates to tariff metering of electrical power drawn from a power distribution grid by a consumer's electric branch circuit as well as to the detection of certain ground faults being present in the electrical branch circuit manifesting as leakage current to ground, and more particularly to improvements in the measuring of current in support thereof.

### BACKGROUND OF THE INVENTION

Electricity meters are devices used to measure the total amount of electrical energy consumed from an electrical service provided through a power distribution grid. The electrical energy is consumed by the consumer's electrical devices coupled that are coupled to the service through electrical branch circuits located on the premises of both residential and business consumers. They can also be used to measure the consumption of electrical energy by an individual electronic device, such as an industrial motor. Electricity meters are designed primarily to measure the consumption of energy in billable units such as kilowatt hours.

For decades, the most commonly deployed type of electricity meter has been the electromechanical watt-hour meter. This meter typically employs a metal disc that is inductively forced to rotate at a speed proportional to the power passing through the meter as current is drawn from the grid at a relatively fixed voltage by the electrical branch circuits of a residence or business. The disc is driven by what is essentially a two-phase induction motor, with the number of revolutions of the disk being proportional to the aggregated energy usage.

More recently, the electromechanical watt-hour meter increasingly is being replaced with what is often referred to as an electronic “smart” meter. The smart meter employs various types of prior art current sensors to sense the magnitude of current being drawn directly from the lines feeding the service to a residence or business. The smart meter typically employs an analog to digital converter (ADC) that samples and digitizes the directly sensed current magnitude information so that it can be processed digitally. Digitizing the sensed current enables a number of additional diagnostic and communication functions that can improve the management of both the provision and consumption of electric power.

One advantage of the digital processing of power consumption information is the ability to determine and analyze power consumption information and report it to the supplier in real time by transmission over a communications network. This information can also be displayed on premises in real time for the benefit of the consumer. Indeed, technology now exists that permits a determination of “true” power consumption based on a true RMS value for the current (which reduces errors introduced by transitory peaks in the current caused by surges on the line), multiplied by the voltage across the service lines, and further multiplied by the power factor (a ratio of the real versus imaginary power).

Real-time monitoring and analysis of power consumption permits the identification of a consumer's times of peak and minimum demand, so that power companies can offer incentives to the consumer to alter consumption to non-peak times of the day (i.e. multiple tariffs). Energy suppliers can also use real-time monitoring of overall demand to reduce the cost of unused standby power during low demand periods. Energy suppliers can also continuously monitor power quality, demand and outages for each consumer. Smart meters can also offer payment processing capability can even permit users to prepay for energy directly using a credit/debit card.

While electronic smart meters offer many potential advantages, these analytical functions are performed at a cost that is directly impacted by the technique chosen to sense the magnitude of the current drawn by the consumer's electrical branch circuit from the service. Prior art electronic or smart meters employ sensor devices that directly sense the current drawn by the consumer's electrical branch circuit from the service line(s) for each phase of the service feeding that consumer's home or business. The level of service dictates the magnitude of the upper end of the current range to be sensed. The upper end of the service range can start at around 60 A and can be as high as 800 A for single phase residential service and many thousands of amps for three-phase industrial installations.

Sensing current directly from the service lines with the requisite accuracy presents significant challenges to prior art current sensing technologies, especially given the large magnitudes and extended ranges over which the current is to be sensed. Overcoming these challenges with traditionally employed prior art sensor technologies requires significant added cost to the current measurement function to support the metering of electrical power. This added cost is multiplied by the many hundreds of millions of consumers of electrical power around the world.

One of the most commonly employed techniques for sensing current to support electronic metering of electrical power requires breaking the service line and inserting a “shunt” resistor directly in series therewith. Precision shunt resistors are fairly low cost components and are reasonably linear over the large current ranges required of metering (except at low current magnitudes). However, employing a shunt resistor in series with the service line for sensing current requires that it have a sufficiently small resistance value to minimize losses due to power dissipation. The small value also minimizes the voltage drop experienced at the upper end of the current range, which is subtracted from the voltage ultimately supplied to the consumer. Those of skill in the art will recognize that, when considered individually, a small voltage drop in the line will account for a relatively small percentage of wasted power dissipated per individual service line (on the order of 2 watts per phase for a 200 amp service). But the collective power lost in the shunt resistor becomes enormous when multiplied by the many hundreds of millions of consumers of electrical power around the world.

In addition, the need to minimize the voltage drop across the resistor necessitates a design tradeoff in that the minimized voltage drop must proportionally represent the entire range of what could be several hundred amps. This lowers the dynamic range of the signal and therefore reduces the signal to noise ratio. This can be particularly problematic for current magnitudes at the lower end of the current range. A small voltage drop also makes it difficult to establish a sufficiently accurate digitized voltage value from which the current magnitude can be accurately derived and digitized. This requires that the voltage across the shunt resistor be amplified, usually with an operational amplifier, to present a usable voltage for purposes of digitizing the voltage. As a result, metering at the lower end of the current range is particularly inaccurate, leading to the inaccurate billing of consumers when drawing current at the lower end of the current range.

As previously discussed, one of the advantages of smart metering is that it renders the current and voltage measurements as digital values for ease of processing. The conversion of analog values to digital ones is typically performed by an analog front end (AFE) circuit of the smart meter. The digital processing circuitry can include a specially programmed microcontroller/processor, memory and network communications circuitry. Because employing shunt resistors in series with the service line means that the shunt resistor is at full line voltage (which is typically about 110 volts in the US but is sometimes 220 volts in the US, and can be 240 volts in other countries), any signal derived from the shunt resistor must be galvanically isolated from the digital circuitry. Providing this isolation adds significant complexity to smart meter designs. Optocouplers are one popular technique by which to achieve this isolation. Another is to use pulse transformers.

For example, Silergy Corporation provides a family of analog front end (AFE) devices that interface with shunt resistors to perform the necessary conversion of the analog value of the voltage drop across the shunt resistor to digital values for processing. In this design, the AFE of the smart meter is formed on its own integrated circuit substrate and is physically isolated from the digital processing circuitry by requiring the digital values generated by the ADC to be communicated to the digital smart meter processing chip through an isolating pulse transformer. This is illustrated in the 71M6xxx Data Sheet published by Silergy Corporation and which is available for download from the Silergy website.

Another way such isolation has been provided by the prior art is to directly couple a current transformer to the service line to perform as the current sensor. The current transformer can be used to sense the current from the service line in lieu of a shunt resistor, and this sensor will serve to inherently isolate the line voltage from the AFE of a smart meter. While the current transformer solution does not have the tradeoff issues regarding accuracy versus small voltage drop, the greater the magnitude of the current to be sensed by the current transformer, the larger and more expensive those current transformers become. Moreover, there is also a cost and size tradeoff regarding the bandwidth of the transformer and its ability to maintain the accuracy of higher frequency harmonics of the sensed current. This can be important if one wishes to perform frequency domain signature analysis of the current drawn by a load to analyze its health performance. Finally, transformers are non-linear at their upper and lower ranges of operation, and that means they must be made larger as the range of the service current increases. Despite the increased cost and size, current transformers are used to sense current for metering in industrial applications because the cost is more easily tolerated for such applications.

Current transformers are often used in the prior art when power metering applications require measurement of the current flowing in the neutral service line (typically single phase service). This is because the National Electrical Code (NEC) requires that the neutral service wire not be broken or interrupted by the insertion of components in series therewith. Thus, if for example, the smart meter is designed to detect the presence of leakage currents in the electric branch circuit of the consumer based on a difference between the magnitude of the service current drawn from the service line and the magnitude of the return current flowing in the neutral line, the return current must be measured by a current transformer. When the difference in current between the service line and the neutral return is measured, and they are often measured using a shunt resistor and a transformer respectively. The differences in their non-linearity are amplified and thus the error in any differential output is magnified.

In sum, prior art current sensing techniques used to support electronic metering are costly and prone to inaccuracy. The shunt resistor is an inexpensive component, but measuring the voltage drop across it requires amplification and galvanic isolation, and it dissipates enormous amounts of power in the aggregate. Transformers are costly both as a function of their required precision, as well as the increased size that is required to accommodate the measurement of the high current magnitudes directly from the service lines. The cost of prior art sensors increases with the magnitude of the current they are required to handle. Adequate component life and reliability over time are difficult to achieve because of the high currents upon which they must operate. Finally, there are additional costs associated with both of these common sensor techniques when interfacing them with the digital components used to perform the requisite processing of the sensed current data.

### SUMMARY OF THE INVENTION

In one aspect of the invention, a method for the manufacture of a ratio metric (RM) current sensor assembly that senses service current drawn by an electrical branch circuit from an electrical service with a predetermined degree of accuracy is taught. The electrical service provides a predetermined range of service current. The method includes providing a current divider between a low impedance conductor and a relatively high impedance conductor, the low impedance conductor being configured to be coupled in series with a service line carrying the service current. A current transformer is provided having a toroidal core magnetically coupled to the higher impedance conductor of the current divider. A predetermined proportionality is targeted to be established between the predetermined range of the service current and a sensed current output voltage of the RM current sensor assembly, the sensed current output configured to be a voltage produced across a burden resistor coupled to a secondary of the current transformer. The targeted proportionality provides a desired range for the sensed current output that falls within the substantially linear range of the current transformer.

The RM current sensor assembly is configured to achieve the targeted proportionality based on at least an estimate of the impedance ratio of the current divider, the turns ratio of the current transformer and burden resistor value of the current sensor assembly. If the established target proportionality is not established to within the predetermined degree of accuracy substantially over the predetermined range of service current, an initial calibration is performed whereby at least the burden resistor is adjusted in value so that for at least one magnitude of the service current range, the sensed current output is equal to an expected magnitude within the predetermined degree of accuracy.

In an embodiment, the at least one magnitude of the service current is the maximum magnitude of the predetermined range of the service current, and the expected value of the sensed current output equals the maximum magnitude of the desired range of the sensed current output.

In an embodiment, the initial calibration includes sourcing a known current of the at least one magnitude of the service current range into the low impedance conductor of the RM current sensor assembly and adjusting the burden resistor value until the sensed current output voltage equals the expected magnitude.

In another embodiment of the invention, the adjusting the burden resistor value is performed by laser trimming the burden resistor once for tooling the RM current sensor assembly for mass manufacturing.

In other embodiments, the adjusting the burden resistor value is performed by laser trimming the burden resistor after the RM current sensor assembly is manufactured.

In another embodiment, at least one of the subprocesses of providing a current divider, providing a current transformer, establishing a target proportionality, configuring the RM current sensor assembly, and performing a first calibration is performed using a computer simulation software program prior to manufacturing the RM current sensor assembly.

In another aspect of the invention, a ratio metric (RM) current sensor assembly that is configured to sense service current of a predetermined range of magnitude within a predetermined degree of accuracy as it is drawn by an electrical branch circuit is manufactured by a process that includes providing a current divider between a low impedance conductor and a relatively high impedance conductor, the low impedance conductor configured to be coupled in series with a service line carrying the service current. A current transformer having a toroidal core magnetically coupled to the higher impedance conductor of the current divider. A target proportionality is established between the predetermined range of the service current and a sensed current output voltage of the RM current sensor assembly, the sensed current output configured to be a voltage produced across a burden resistor coupled to a secondary of the current transformer. The targeted proportionality establishes a desired range for the sensed current output that falls within the substantially linear range of the current transformer. The RM current sensor assembly is configured to achieve the targeted proportionality based on at least an estimate of the impedance ratio of the current divider, the turns ratio of the current transformer and burden resistor value. If the configured proportionality is not within the predetermined degree of accuracy substantially over the predetermined range of service current, performing a first calibration whereby at least the burden resistor is adjusted in value so that for at least one magnitude of the service current range, the sensed current output is equal to an expected magnitude within the predetermined degree of accuracy.

In another aspect of the invention, a ratio metric (RM) sensor assembly senses a service current being drawn from an electrical service through a service line by an electric branch circuit to support electronic metering of the electrical energy consumed thereby, the electrical service being configured to provide a predetermined range of current magnitude at a fundamental frequency. The RM sensor assembly includes one or more RM current sensor assemblies that each have a current divider formed of a low impedance conductor, and a higher impedance conductor coupled at two points along the lower impedance conductor. The low impedance conductor is configured to be conductively coupled in series with a service line carrying the service current drawn by the electrical branch. Each of the one or more RM current sensor assemblies also includes a current transformer that includes a toroidal core through which the higher impedance conductor is fed as a primary winding, and a secondary formed of one or more windings about the core and coupled to a burden resistor that is coupled to the secondary.

The RM current sensor assembly is configured to produce a sensed current output across the burden resistor that has a predetermined operational range of magnitude that is proportionally related to the sensed service current over the predetermined operational range of the service current. The burden resistor of the RM current sensor assembly is configured to have a value that sufficiently compensates for inaccuracies in at least the impedance ratio of the current divider to ensure that the sensed current output is within the predetermined degree of accuracy over the predetermined operational range of the sensed current output.

In a further embodiment, the burden resistor of the RM current sensor assembly is configured to have a value that sufficiently compensates for inaccuracies in at least the impedance ratio of the current divider to ensure that the sensed current output is within the predetermined degree of accuracy over the predetermined operational range of the sensed current output.

In another embodiment, the predetermined range of the service current is apportioned into one or more contiguous segments, and each of the one or more RM current sensor assemblies is assigned to sense current for one of the one or more segments. The proportionality for each of the assigned RM current sensor assemblies is configured such that it operates over a substantially linear portion of its operational curve when the magnitude of the service current being drawn through the service line falls within the segment to which it is assigned.

In a further embodiment, a multiplexor is configured to select the sensed current output of the one of the one or more RM current sensor assemblies assigned to the segment within which the magnitude of the service current presently resides.

In a still another embodiment, each of the one or more current sensor assemblies are associated with a calibration profile, the calibration profile including a plurality of pairs of calibration values generated by sourcing a known AC current of the fundamental frequency into a calibration RM current sensor assembly that has the same configuration as the at least one RM current sensor assembly, the sourced current being swept in magnitude from the lowest to the highest magnitude of the predetermined range of the service current, and then for each one of a plurality of specified magnitudes of the known AC current, storing in a non-transient memory a pair of digitized values representing the specified magnitude of the known AC current and the sensed current output generated by the specified magnitude of the known AC current.

In an embodiment, the one or more RM current sensor assemblies are calibrated using the calibration profile by performing a best match between the sensed current output values of the calibration profile and periodic digitized samples of the sensed current output magnitude produced by the RM current sensor during operation, and substituting the known AC current magnitude associated with the best matched sensed current output as the sensed magnitude for the service current for each of the digitized samples.

In another aspect of the invention, a ratio metric (RM) differential current sensor detects leakage current to ground present in an electric branch circuit drawing service current from an electrical service. The RM differential current sensor assembly includes a first current divider formed of a first low impedance conductor configured to be conductively coupled in series with a service line carrying the service current to the electrical branch circuit and a first higher impedance conductor coupled at two points along the lower impedance conductor. The RM differential current sensor assembly further includes a second current divider formed of a second low impedance conductor configured to be conductively coupled in series with a neutral service line carrying return current back to the service and a second higher impedance conductor coupled at two points along the second lower impedance conductor. The RM differential current sensor assembly further includes a differential current transformer that includes a toroidal core through which the first and second higher impedance conductors are fed as primary windings and a secondary formed of one or more windings about the core and coupled to a burden resistor that is coupled to the secondary.

The RM differential current sensor assembly is configured to produce a sensed differential current output across the burden resistor, the sensed differential current output indicating a degree of imbalance between the current flowing in the service line and current flowing in the neutral line indicating the presence of leakage current to ground being present in the electric branch circuit.

### BRIEF DESCRIPTION OF THE DRAWINGS

FIG. 1 is an illustration of a typical split phase (or “three-line, single-phase”) electric power service, coupled to the electrical distribution system of a premises;

FIG. 2 is a block diagram illustration of a prior art smart meter assembly, incorporated within the electrical distribution system of FIG. 1, to meter power drawn by the service as well to provide other signal processing functions based on the current drawn by from the service by the electrical distribution system of the premises;

FIG. 3 is a simplified circuit block diagram of the prior art current sensors commonly employed as a part of the smart meter assembly to continuously sense the load current being drawn from the service of FIG. 1 and to provide an analog output to the smart meter representing the magnitude of the drawn load current over time;

FIG. 4 is a circuit diagram illustrating an RM current sensor assembly of the invention;

FIG. 5 is a circuit diagram of a differential current sensor assembly of the invention;

FIG. 6 is a block diagram illustrating replacement of the prior art sensors of FIG. 3 with an RM current sensor assembly FIG. 4 and the RM differential current sensor of FIG. 5;

FIG. 7 is a circuit level block diagram of the RM current sensor assembly and the RM differential circuit sensor as deployed together as an RM sensor assembly of FIG. 6.

FIG. 8A is an example of a B v. H curve for a toroidal transformer;

FIG. 8B is the average B v. H curve for the curve of FIG. 8A; and

FIG. 8C is a representation of the division of the full range of current into three contiguous segments each sensed by one of three separately dedicated RM current sensors of the invention to improve the accuracy of the sensed current over the range of current of a given service level; and

FIG. 9 is a block diagram illustrating the use of two or more of the RM sensor assemblies of FIG. 4, each having its own specific proportionality best suited to its assigned one of the segments of the total current range to be metered.

### DETAILED DESCRIPTION

Measuring current with the accuracy required for supporting the electronic metering of power consumption while maintaining reasonable cost and compatibility with digital smart meter circuits presents significant challenges. Well-known prior art current sensing technologies necessitate undesirable design tradeoffs between cost, size, unnecessary power dissipation, processing compatibility and performance. Accuracy of the current measurement is important not only to ensure accurate billing of consumers, but also can be critical to the integrity of any post-processing use of the sensed information in controlling the distribution of the service and monitoring the health of each consumer's branch circuit. Shunt resistors as current sensors are themselves inexpensive, but their implementation can be complex as they require support circuitry to accurately measure and amplify the small voltage drop across them, as well as requiring additional circuitry to provide galvanic isolation for signals provided to the smart meter. Moreover, they are wasteful in the cumulative power they dissipate.

Embodiments of a ratio metric (RM) current sensing method, RM current sensor assembly, RM differential current sensor assembly and RM smart meter current sensor assembly are disclosed that can replace known prior art sensors and differential amplifiers to measure current in support of various electronic (“smart”) metering functions. The various embodiments of the invention leverage a ratio metric design to significantly reduce the size and complexity of sensing, thereby lowering the cost of these metering functions while significantly improving the accuracy of current measurement function over the full range of the current to be measured.

Embodiments of the invention not only enable lower cost and more accurate measurement of the line current for determining power consumption, but they also facilitate the cost-effective implementation and performance of various other desirable diagnostic functions that can be included as part of the electronic metering process. Such functions can include the ability to monitor the operational status of the consumer's electric branch circuit. These advantages will be apparent to those of skill in the art in view of the following detailed description.

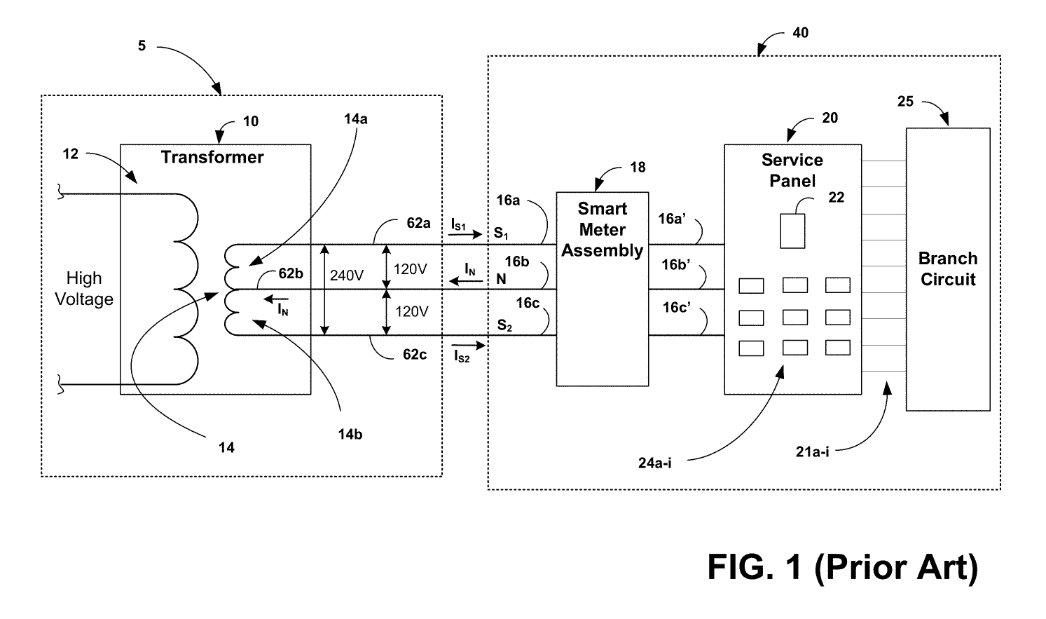

FIG. 1 illustrates a typical single-phase, three-line residential electrical power service 5 deployed in the United States. Those of skill in the art will appreciate that this form of service is being used as an example only, and that the embodiments of the invention disclosed herein are not intended to be limited thereto. Those of skill in the art will appreciate that application of the embodiments of the invention can be extended by example to any type of electrical service.

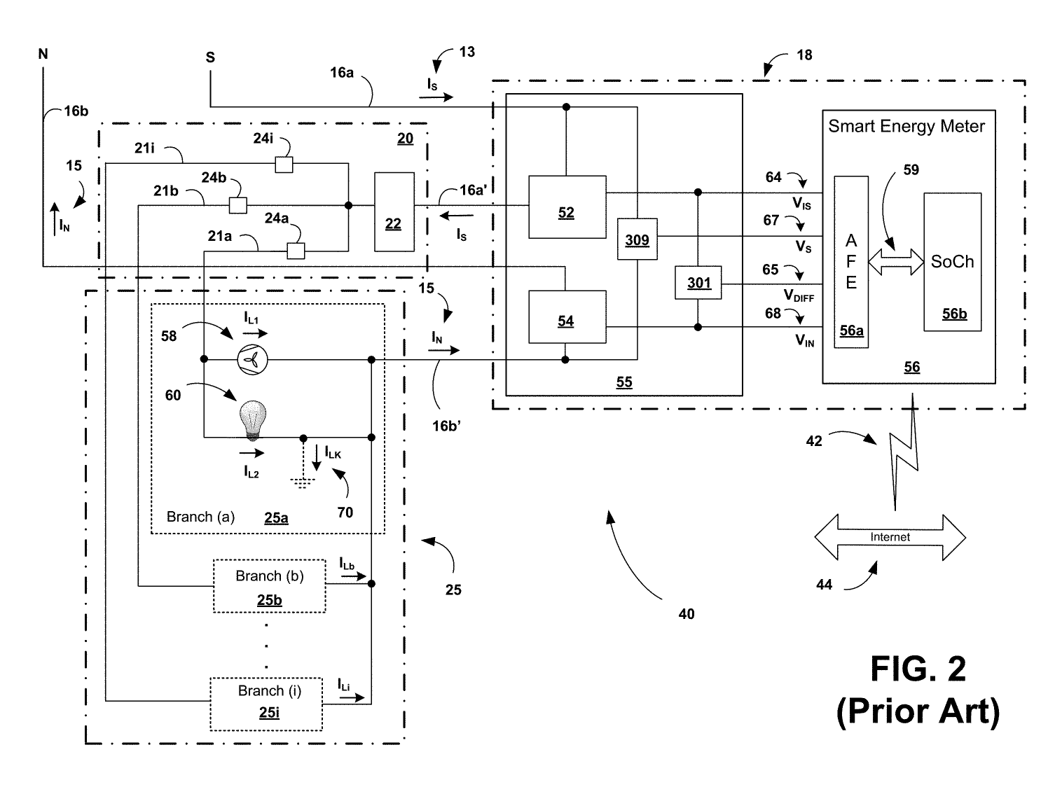

Transformer 10 of service 5 steps the voltage down using a primary coil 12 to secondary coil 14 to produce a single-phase supply of 240 volts across secondary coil 14 and lines 62a and 62c. Coil 14 is then split into halves 14a and 14b using a coil tap in the form of neutral wire 62b, so that the single phase 240-volt supply is divided into two split-phases S₁ and S₂, of 120 volts each. These voltages are provided to the electronic distribution system 40 for a premises (e.g. a residence) between service lines S₁ 16a/N 16b and between service lines S₂ 16c/N 16b. Those of skill in the art will appreciate that this service configuration permits a resident of the premises to run smaller appliances and resistive loads (such as resistive lighting element 60 and appliance fan 58 of FIG. 2) using one of the 120-volt (split-phase) service lines S₁ 16a or S₂ 16c in conjunction with neutral service line N 16b, and to run load devices such as air conditioners at the full 240 volts provided between service lines S₁ 16a and S₂ 16c.

As previously discussed, the service lines S₁, N, S₂ (16a-c respectively) can be coupled to the electrical distribution system 40 of a residence or commercial building for example, that can include an electronic (“smart”) meter assembly 18 (in lieu of a prior art watt-hour meter based on an electromechanical design). Smart meter assembly 18 electronically meters the power drawn by a consumer during some fixed billing period. Meter assembly 18 includes an electronic (“smart”) meter (56, FIG. 2) that measures the current directly from service lines 16a (S₁), 16c (S₂) and neutral N 16b. Those of skill in the art will appreciate that most residential and small business consumers will typically use only one of the two wires S₁ 16a′, S216c′ to run one half of the single phase voltage (120 volts as illustrated) to the service panel 20 of FIG. 1. Thus, for purposes of simplicity, the following discussion will represent the split-phase service wires as S 16a and N 16b.

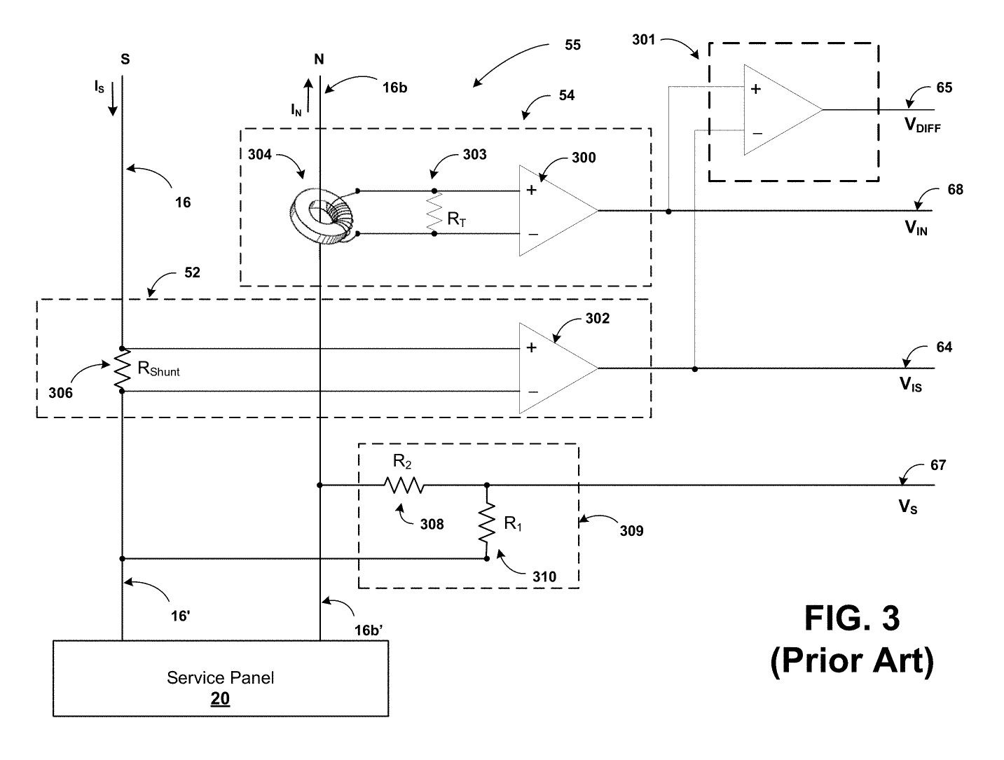

FIG. 2 illustrates a simple block diagram representation of the prior art electrical distribution system 40, electrically coupled to the Single Phase Two Wire service 5 of FIG. 1 through service lines S 16a and N 16b. Electrical distribution system 40 includes an assembly of sensors 55 that provides output voltages as signals that are utilized by the smart energy meter 56. Sensor assembly 55 includes a current sensor 52, coupled to line S 16a to sense the current being drawn through line S 16a from the service by the branch circuit 25. The current is passed through sensor 52 to the service panel to the branch circuit 25 through line 16a′. Current sensor 52 will be presented in more detail below with reference to FIG. 3

Sensor 52 continually senses the drawn current I_{S} 13 and typically provides an output voltage V_{IS} 64 to the smart meter 56, the value of which is proportional to the sensed current at any given time. Sensor assembly 55 further provides an output V_{S} 67 that is proportional to the line voltage V_{S} 67 via voltage divider 309, which continuously represents the voltage being presented by the service across the branch circuit by the service between service lines S 16a and N 16b. Voltage divider 309 will be presented in more detail below with reference to FIG. 3. From these two signals V_{IS} 64 and V_{S} 67, smart meter 56 can calculate continuously the power being consumed by the branch circuit 25 over some predetermined interval of time for billing purposes.

The current I_{S} flows through sensor 52 into the panel 20 via S 16a′ through main circuit breaker 22, through individual breakers 24a-i and into the respective branches 25a-i though lines 21a-i respectively. Only a few of the branches 25 are shown for brevity. Each branch of the branch circuit 25 typically distributes one of the split-phase lines S 16a′ to various load devices (e.g. lights, fans appliances, etc.) coupled to the electrical branch circuit 25. The circuit breaker 24(a-i) for each branch can be actuated manually and can be tripped opened automatically when the load current drawn by devices coupled to the branch exceeds a predetermined threshold indicating the presence of a short-circuit. As previously discussed, main breaker 22 can be automatically or manually actuated to disconnect the service line S₁ 16a′ from the entire electrical branch circuit 25.

Branch 25a is a simplified example to show two load devices fan 58 and light fixture 60 coupled thereto. Fan 58 draws load current I_{L1}and light fixture 60 draws load current I_{L2}, which are then recombined with currents drawn by the other branches 25 (i.e. I_{Lb}-I_{L1}) and returned as I_{N} 15 through line service line 16b′ to the smart meter assembly. I_{LK} 70 is a potential leakage path to ground, otherwise known as a ground fault. When no leakage current is present in the branch circuit 25, return load current I_{N} 15 flowing through the neutral service lines N 16b′, 16b will be virtually equal to service load current I_{S} 13. When leakage current is present, I_{LK} 70 will be subtracted from the total return current I_{N} 15.

Returned service load current I_{N} 15 can be sensed by a second current sensor 54 that can be deployed to directly sense the magnitude of the AC current I_{N} 15 flowing in the split-phase service line N 16b. Prior art current sensor 54 senses the magnitude of the return AC current I_{N} 15 flowing in the neutral service line N 16b and provides an output V_{IN} 68 to Smart Meter 56 representing the magnitude of the return current I_{N} 15. Current sensor 54 is also presented in more detail below with reference to FIG. 3. Differential current sensor 301 of sensor assembly 55 can be used to detect the difference between the outputs of the two sensors 52, 54 using, for example, as a differential amplifier, the difference being a voltage output V_{DIFF} 65 that is proportional to any leakage current I_{LK} 70.

The voltage outputs V_{IS} 64, V_{IN} 68, V_{DIFF} 65 and V_{S} 67 from the current sensor assembly 55 are provided as inputs to an analog front end (AFE) 56a of processing device 56. AFE 56a typically includes an Analog to Digital (A/D converter) that digitizes samples of the voltages of outputs V_{IS} 64 and V_{IN} 68 and are converted to the current values they represent as the currents are directly sensed by sensors 52 and/or 54 respectively. Output V_{S} 67 is sampled and converted to digital values of the line voltage. The smart meter processing device 56 also includes digital circuitry in the form of SoCh (system on a chip) 56b, including a microprocessor and associated software, that calculates the power consumption using the digitized samples of the sensed current I_{S} 13 to establish the RMS value of the current I_{S} 13. These RMS values are multiplied by the voltage sampled at V_{S} 67, along with the calculated power factor, and are then aggregated over predetermined time period (e.g. a month) to establish the power consumed over that period of time. The presence of values of V_{DIFF} 65 that exceed some predetermined threshold can be used to turn on a warning light to indicate the presence of leakage current in branch circuit 25.

Those of skill in the art will appreciate that the smart meter processing device 56 can be one of a number of commercially available proprietary designs. One such device is the MCF51EM256 microcontroller manufactured by Freescale Semiconductor. Another is the MAX71020 single chip meter made by Silergy Corporation. These exemplary devices, or variants thereof, can be used as device 56b of smart meter 56. Typically, they are designed to be compatible with a proprietary requisite analog front-end (AFE) 56a as part of the overall design and communicate with one another through an interface 59.

SoCh 56b is the digital signal processing portion of the smart meter that typically includes a microprocessor of some kind and non-transitory memory for storing software executed by the microprocessor. Processing portion 56b, in addition to calculating energy consumption by the electrical distribution system 40, can perform various additional processing functions using the digitized data. For example, it can be programmed to compensate for various environmental conditions such as temperature and altitude and providing network communication function by which the calculated information can be logged and transmitted to the power supplier for analysis and billing. It can also be programmed to monitor parameters that reflect the well-being of the electrical distribution system 40, including the appliances and other load devices coupled thereto. It can be programmed to analyze the load current for indications of the presence of faults that can lead to fire or hazardous conditions such as faults.

SoCh 56b will also typically include the ability to connect to the Internet 44 over some network connection 42 which can be hard wired or wireless. This will enable the metering information as well as functional status and well-being information to be transmitted back both to the service provider as well as the user. Those of skill in the art will appreciate that the fine details of the smart meter designs are well-documented and are outside the scope of this disclosure, which is directed to improvements in the sensor assembly employed to provide the input signals required by such smart meter chip sets.

Interface 59 facilitates transfer of the digitized form of the input signals, generated by the AFE 56a, to the SoCh digital processing circuitry 56b. Those of skill in the art will appreciate that this interface can be complex, not only to provide signals that can be processed by the SoCh circuitry, but also to provide galvanic isolation between the two circuits given that they will typically be operating at disparate voltages. This is especially true if the current sensor 52 is operating at the line voltage of 120 volts in the example of FIG. 1.

As illustrated in FIG. 3, prior art current sensor 52 of the sensor assembly 55 is typically implemented as a precision shunt (series) resistor R_{SHUNT} 306, which is placed in series with the split-phase service line S 16a. The voltage across R_{SHUNT} 306 is deliberately kept small to minimize the voltage loss in the S 16a service line, as well as to minimize power dissipation by R_{SHUNT} 306. An amplifier 302 (and other associated circuitry) is therefore typically used to amplify the small output voltage drop across R_{SHUNT} 306 to provide V_{IS} 64 as a viable signal to proportionally represent the magnitude of current I_{S} 13.

While it is not generally required by code that the current flowing in the neutral path N 16b be measured, it can be useful to do so if one wishes to detect the presence of leakage current in the branch circuit 25 of the premises. Those of skill in the art will appreciate that the relatively less expensive shunt or series resistor 306 of sensor 52 is not permitted to be used for sensing current in the neutral wire N 16b. The neutral service wire N 16b, in accordance with the National Electrical Code (NEC), is not permitted to be broken or interrupted with components in series therewith. The neutral service wire is required to be bonded to ground at the head of the service. Interrupting N 16b with a component such as R_{SHUNT} 306 creates a voltage drop between neutral and ground and poses the possibility that a failing component can cause N 16b to rise to a voltage level near that of service line S 16a (e.g. 120 volts) within the premises to which the service is being provided. This is an impermissible hazard.

Current sensor 54 is therefore one that must provide galvanic isolation, such as one magnetically coupled to the neutral service line 16b, 16b′ as a toroid current transformer. Sensor 54 employs a core 304 through which line N 16b, 16b′ passes. This permits current flowing in neutral line N 16b, 16b′ to be sensed without physically interrupting it. The secondary windings of the transformer are coupled to burden resistor R_{T} 303. The voltage across R_{T} 303 is amplified by amplifier 300 to create an output V_{IN} 68, which proportionally represents the current I_{N} 15 flowing through the neutral conductor 16b. V_{IN} 68 is derived from the voltage drop across RT 303 and the turns ratio of the toroid transformer 54. As previously discussed, the potentially large currents drawn by a large load premises will require a large and very costly transformer for that purpose, which discourages sensing the neutral current to identify leakage current at the service current level.

As illustrated in FIG. 2, the presence of a ground fault can lead to the flow of leakage current I_{LK} 70 flowing to ground in one or more of the branches. This leakage current will be reflected as an imbalance between the current flowing in neutral line N 16b, 16b′ and the current flowing in the service lines that is roughly equal to the magnitude of the leakage current I_{LK} 70. As illustrated in FIG. 2 and FIG. 3, a comparison of the current sensed by sensor 52 and the current sensed by sensor 54 can be accomplished through a circuit such as a differential op-amp 300 or other suitable comparative technique, which determines the difference and amplifies it to produce voltage output V_{DIFF} 65. This difference in current magnitude is input into the AFE 56a of smart meter 56 and if the difference represented by I_{LK} 70 reaches and/or surpasses some predetermined threshold, the presence of a ground fault can be inferred therefrom.

It should be noted that while it has been suggested in the prior art that it might be desirable to sense the return load current in the neutral service line when using smart meters, it is unclear if this is ever implemented in practice because of the additional expense to provide the necessarily large and expensive toroid transformer as a current sensor to measure the high magnitude of current in the neutral line. It also adds complexity to provide the requisite circuitry to detect and amplify the difference between outputs of two different types of sensors. While there are benefits to testing for leakage current at the service metering level, it may be the prevailing belief in the art that the expense for such testing can be avoided because devices already exist to detect leakage at the branch level and any additional benefit may not be warranted in view of the additional cost.

Because the sensor 52 is most typically a shunt resistor 306 in prior art sensor assemblies 55, sensor 52 operates at the full service line voltage S 16b. This will require that interface 59 provide galvanic isolation between the AFE 56a and the SoCh 56b because they are processing signals at two disparate voltage levels. Such isolation schemes can include opto-isolation and pulse transformer circuits, which are currently employed in the AFEs of existing smart meter chips designed to interface with shunt resistors.

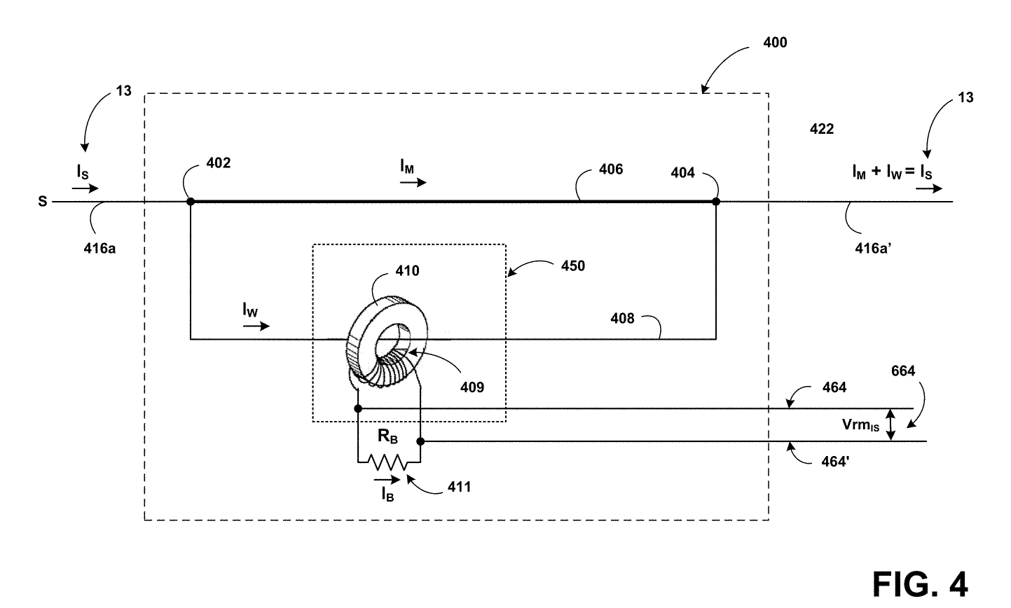

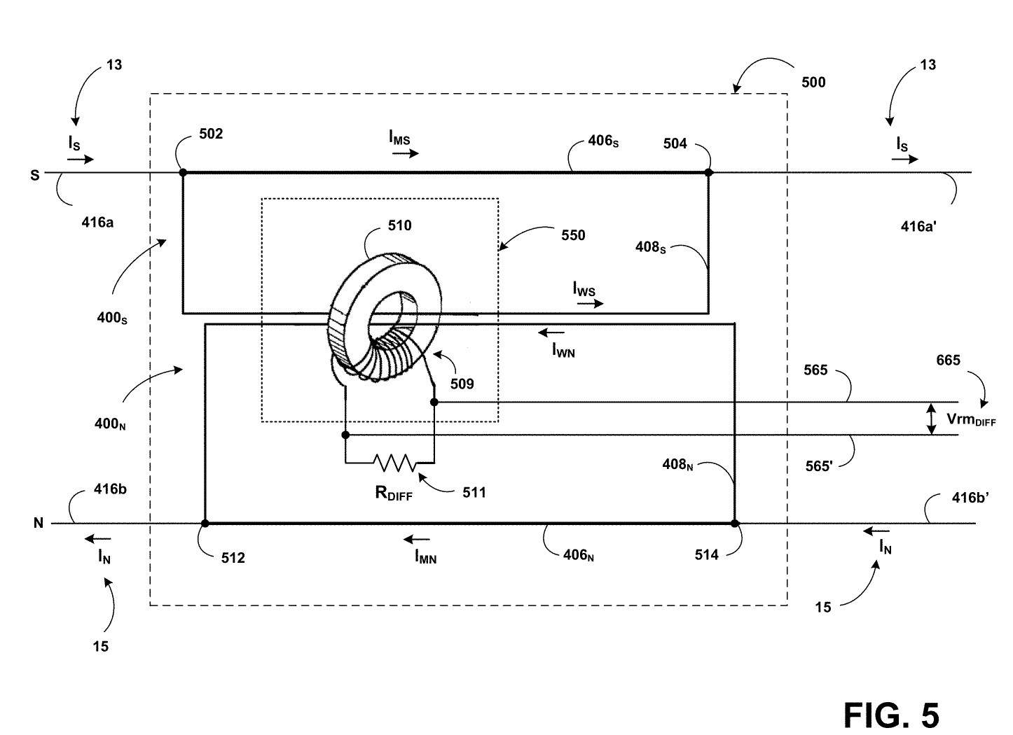

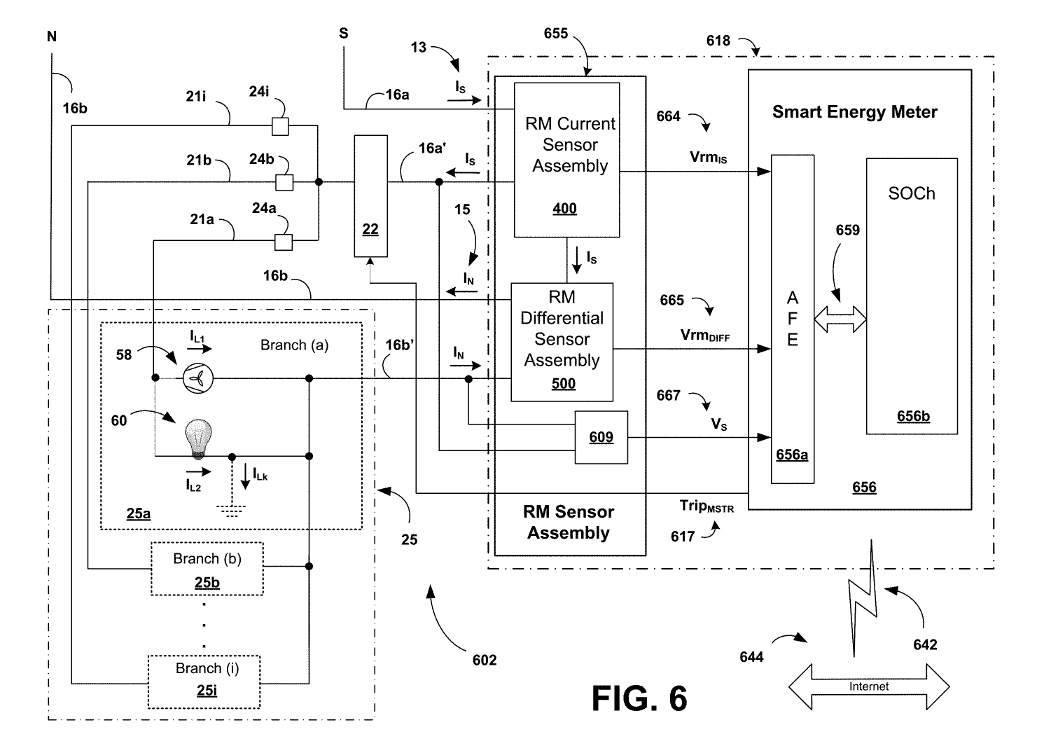

FIG. 6 illustrates an RM sensor assembly 655 that replaces the prior art current sensor assembly 55 of FIGS. 2 and 3. Ratio metric current sensor assembly 400 replaces sensor 52, which is typically a shunt resistor and associated amplification circuit 302 as previously described (FIG. 3), and RM differential current sensor assembly 500 replaces large current transformer sensor 55 and differential amplifier 301, (FIG. 2). RM current assemblies 400 and 500 will be discussed in more detail below with reference to FIGS. 4 and 5 respectively below. Voltage divider 609 is largely the same as that of the prior art (309, FIG. 3). Both RM sensor assemblies 400 and 500 of RM sensor assembly 655 leverage current dividers that can be configured and manufactured using PC board technology to indirectly sense the service current I_{S} 13 that enables the use of small toroidal transformers 450, 550 respectively. The toroidal transformers 450, 550 are inexpensive, simple to mount on PC boards and provide the requisite galvanic isolation that shunt resistor 52 does not. Reducing the current actually sensed to a fraction of the full service current I_{S} 13 drawn by a premises enables the toroidal transformer 450, 550 to be reduced substantially in both size and cost from the current transformer that otherwise would have to be used to accurately sense the service current directly from the service lines while maintaining bandwidth (the reason prior art sensor 54 is not used), and eliminates the disadvantages of using a shunt resistor as previously discussed.

FIG. 4 illustrates an embodiment of a ratio metric (RM) current sensor assembly 400 of the invention that can directly replace the prior art sensor 52 of the smart meter sensor assembly 55 of FIGS. 2 and 3. Sensor assembly 400 can be configured to provide a significantly smaller, less costly and more accurate current measurement device to support tariff metering of electric power using smart meters compared to sensors heretofore employed in the prior art such applications as described above. In addition, bandwidth is preserved when sensing these high magnitude currents, which supports accurate wellness monitoring of the electrical distribution system (600, FIG. 6) and more particularly, the branch circuit (25, FIG. 6). With respect to the return current I_{N} 15, it should be noted that most applications do not typically require that smart meter (656, FIG. 6) receive a direct measurement output V_{IN} 68 for the value of the return current. The sensed return current is typically only used in conjunction with a differential amplifier to provide an indication of leakage current as previously discussed. Notwithstanding, an RM current sensor assembly 400 of the invention would be sufficiently cost-effective to provide such a sensed current output to a smart meter assembly (656, FIG. 6) if one if is desired.

As shown in FIG. 4, a low impedance conductor 116a to 116a′ is provided as a wire or PC board trace that can be placed in series with (and has substantially the same conductivity as) the service line S 16a in lieu of the shunt resistor 52 of the prior art. A second conductor 408 of relatively higher impedance compared to the phase line S 16a and conductor 116a to 116a′, is provided as a flexible wire or PC board trace that is fed through a core 410 to form a primary of the toroid inductor of a toroidal current transformer 450.

Conductor 408 is further conductively coupled to conductor 116a to 116a′ at points 402 and 404 respectively. This establishes a current divider having a main path 406 that incorporates conductor 116a to 116a′ and a secondary high-impedance path formed by conductor 408. Based on the relative impedances of the two paths, the AC current I_{W} flowing in the secondary path of the current divider formed by the wire 408 can be made proportionally much smaller in magnitude than the current I_{M} flowing in the main path 406 formed by the portion of low impedance conductor 116a to 116a′ between points 402 and 404.

Those of skill in the art will appreciate that this same current divider can be configured by conductively coupling the high-impedance conductor 408 directly to the service line 16a to 16a′ if practicable. Those of skill in the art will appreciate that the first calibration as discussed below would have to be conducted in circuit for each installation rather than as part of the process of manufacturing a standardized device.

A burden resistor R_{B} 411 having a predetermined resistance value is coupled across the secondary 409 of toroidal current transformer 450. The current I_{B} flowing through burden resistor R_{B} 411 is equal to: the voltage drop across R_{B} 411 (between lines 464, 464′), divided by the value of R_{B} and is the sensed current output Vrm_{IS} 664 of the RM current sensor assembly 400. The current I_{W} flowing through the wire 408 is equal to I_{B} divided by the turns ratio of toroid 450. The magnitude of the current I_{S} 13, which is drawn from the service by the branch circuit of the premises and flows through phase line S 16a and conductor 116a to 116a′ can be derived by multiplying I_{W} by the complex current ratio between I_{M} and I_{B} to ascertain I_{M}, and then adding I_{M} and I_{B} to get I_{S} 13.

The conductor forming secondary path 408 can be a flexible wire to ensure its easy threading through the core 410, and to maintain sufficient distance from the main path conductor 406, thereby eliminating electro-magnetic interference that is common to monolithic prior art implementations of current divider based current sensors. Any wire used for secondary path 408 is preferably insulated, which will prevent short-circuits between the wire 408 and other proximate conductive paths. The core 410 is preferably conformally coated and can be directly mounted to a printed circuit board (PCB). Those of skill in the art will recognize that if the wire 408 and the main path 406 are implemented as traces on a PCB, they can also be separated and insulated from one another by, for example, locating each on a different interconnect level on the PCB. In either case, it will be appreciated that it will not be difficult to avoid electromagnetic interference by ensuring that there is sufficient distance between the wire forming the secondary path 408 of the current divider and the main path formed by the conductor 116a, 116a′ between the points 402 and 404.

Those of skill in the art will appreciate that there are a number considerations that affect the accuracy of the RM current sensor assembly 400 in sensing service current for metering purposes. First, the classes of service current can range from 60 amps at the lower end of residential service to 800 amps for industrial three-phase service. The typical target for accuracy in current metering applications is 1% but should be as accurate as practicable. It is highly unlikely that such an accuracy is being achieved over the entire range of such large magnitude current ranges with smart metering products as limited by prior art current sensor technology. The RM current sensor assembly 400 can be manufactured and implemented to achieve this level of accuracy in view of the following description of a method of manufacturing.

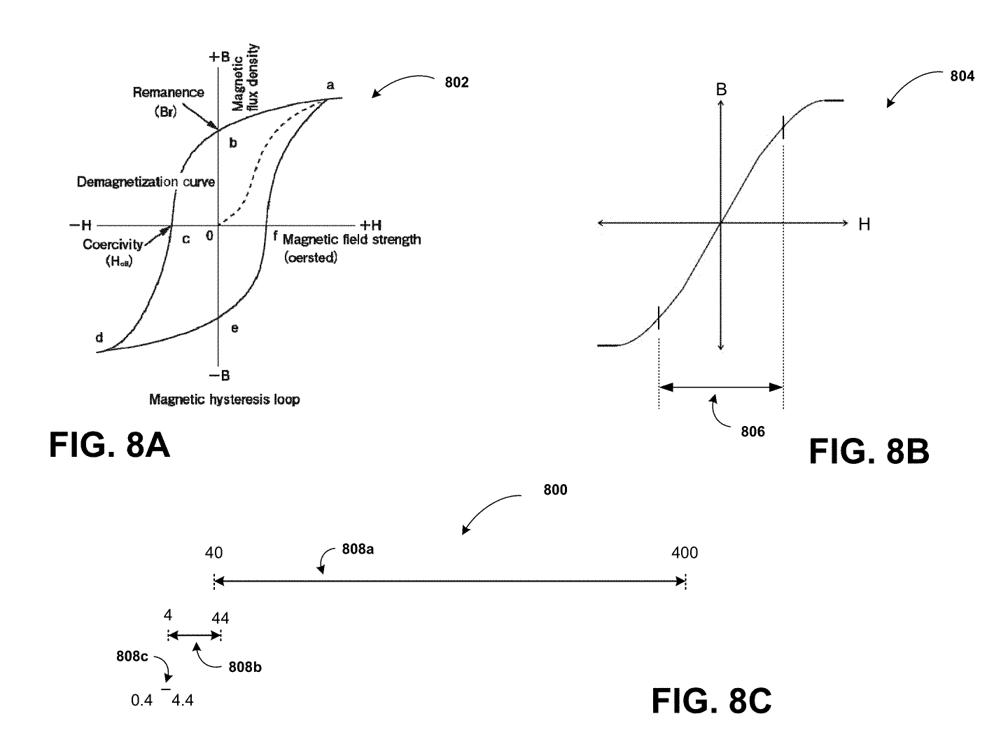

Those of skill in the art will appreciate that ideally, the overall proportionality of the RM current sensor assembly 400, between the service current as its input and the sensed current output Vrm_{IS} 664 across the burden resistor R_{B} 411, would be constant across the whole range (i.e. would be linearly proportional). Those of skill in the art will recognize that a toroidal current transformer has a B-H curve as shown generally in FIG. 8A and an average B-H curve as generally illustrated in FIG. 8B. While the curve is substantially linear up to a certain magnitude of current for a given core and number of turns, eventually the core saturates and the response to further increases in the magnitude of the service current becomes increasingly non-linear. It will be appreciated that because the toroid can be reduced in size and cost significantly by dividing the current that is actually sensed, the core size and material can be optimized to minimize the magnetic hysteresis loop for the toroidal current transformer, thereby improving its overall performance.

Those of skill in the art will recognize that a toroidal current transformer that could operate at a substantially linear response over a range of high magnitude current such as may be drawn from a 200 amp electrical service would be very large and costly. The current divider of the current sensor assembly 400 can be used provide a substantial ratioing of the currents such that the size of the core can be significantly reduced while still operating within the substantially linear portion its B-H curve. However, prior art attempts to incorporate a current divider with a toroidal current sensor device have largely failed to produce practicable embodiments. This is because they have been manufactured under the initial premise that one must first manufacture the current divider to a high degree of accuracy. This led to expensive, bulky, monolithic, devices that are hard to manufacture and have high frequency issues caused by magnetic cross-coupling between the conductive paths of the current divider.

The RM current sensor assembly 400 is instead manufactured from the premise that one can establish a target proportionality (which includes manufacturing the current divider to approximate a desired current ratio) of the current sensor assembly 400, and then calibrating out the inaccuracy in the parameters that affect the physically realized or actual proportionality to achieve the required degree of accuracy through simple adjustment of the of burden resistor R_{B} 411 value as part of the manufacturing process. This permits the current sensor assembly to be manufactured using less expensive printed circuit board techniques through calibration.

Thus, for a given range of service current, a target proportionality can be formulated for a toroidal transformer of a given size and core material that can be optimized for size and cost, as well as reducing the width of the magnetic hysteresis loop of the B-H curve 802 as illustrated in FIG. 8A. This permits the current transformer to operate over a predetermined range of service current while remaining substantially within the more linear portion of its operation. For example, one can start with a desired core size and material for the current transformer that optimizes the size and cost of manufacture, and to provide a desired dynamic range of output voltage for Vrm_{IS} 664 based on its operational curve. Based on the maximum current of the current range of the service provided by service line S 16a, one can specify a desirable current divider ratio and turns ratio that will produce the desired output voltage range for Vrm_{IS} 664 while maintaining the current transformer within its substantially linear range of operation. This desired output range can be, for example, about 0.2-5 volts. To achieve a range of 0.2 to 5 volts for Vrm_{IS} 664 over the current range of a 200 amp service, the current I_{W} flowing in the secondary path could have a desirable range of about 50 milliamps at the top of the range, down to about 2 milliamps at the lower range based on the configuration of the current transformer. If a current transformer is implemented with a single turn in the secondary so that it produces the same current that flows through the secondary path of the current divider, and the value of R_{B} 411 is initially predetermined to be 100 ohms, the current ratio required would be about 4000 to 1 and the voltage signal across R_{B} 411 would be 0.05×100=5 Volts at the top of the output range. Thus, conductors forming the two paths can be specified based on, for example, their estimated resistance values to produce such a ratio.

Those of skill in the art will appreciate that one could perform this configuring of the current sensor assembly to achieve a target proportionality for a current transformer that is optimally sized for cost and linear operation, by building a physical circuit and physically manipulating circuit components to arrive at a combination of circuit parameters that achieves the target proportionality. However, it may be more expedient to first employ one of the myriad of commercially available circuit design software tools that permits one to simulate the circuit using software by which to arrive at a desired configuration that achieves the targeted proportionality. This includes specifying the geometric proportions of the conductive paths by which to achieve the desired current/impedance ratio of the current divider. The configuration can be verified to approximate the target proportionality without iteratively manufacturing, adjusting and re-testing.

Notwithstanding, at some point the current sensor assembly 400 is then physically configured (i.e. assembled/manufactured) as part of the configuration process. Manufacturing the physical circuit produces a current sensor assembly with an actual proportionality that can be tested to see if it produces the requisite accuracy. This is because the simulated or calculated configuration is based on a theoretical configuration including estimates of the current divider impedance ratio and the proportionality of the current transformer 450. If the actual proportionality realized by manufacturing the current sensor assembly fails to achieve the requisite accuracy, various forms of calibration described below can be used to bring the current sensor assembly within the predetermined degree of accuracy specified for the application.

It will be appreciated that the actual proportionality will not be the targeted one due to the estimations of the impedance ratio of the current divider and imprecision in the proportionality of the current transformer, and the calibrations discussed below are not intended to more closely meet the targeted proportionality. Rather, the actual proportionality of the current sensor assembly is now accepted as the overall proportionality of the circuit, and the calibrations simply ensure a more accurate operation of the RM current sensor assembly 400 at the actual proportionality. Thus, the targeted proportionality is only an approximation to get the current sensor assembly into a range of proportionality that ensures reasonable linearity of its operation at a desired size and cost. By freeing the manufacturing process from the constraint of having to achieve accuracy at a predetermined proportionality as has been done in the past, the manufacture and implementation of the RM current sensor assembly 400 can achieve a far more practicable implementation using a current divider as part of a current sensor.

An initial calibration can be performed to achieve a first level of accuracy of the actual proportionality by sourcing into node 402 a known current equal to the maximum value of the current range of service to be metered, and measuring the sensed current output to determine if it equals the expected value of 5 volts within the requisite degree of accuracy. Those of skill in the art will appreciate that to achieve a 1% accuracy for metering current, this is not likely to be the case. Thus, the value of the burden resistor R_{B} 411 can be adjusted until the magnitude of the output Vrm_{IS} 664 equals the maximum value of the desired output range for the sensor assembly 400 (e.g. 5 volts) within the predetermined degree of accuracy. Thus, a single and easy to adjust parameter of the RM current sensor assembly can calibrate out any of the error introduced into its proportionality between the service current at its input and its sensed current output, due to the imprecisely known impedance ratio of the current divider and/or the imprecisely known proportionality of the current transformer. And this calibration serves to increase the accuracy of the actual proportionality of the current sensor assembly, NOT the inaccuracy between the actual proportionality and the targeted proportionality.

Those of skill in the art will appreciate that the value of R_{B} 411 can be adjusted a number of ways. For example, it could be done iteratively by replacing the physical component with different values until the required degree of accuracy is achieved. The R_{B} 411 could also be implemented in a manner that would allow for it to be laser trimmed until the required degree of accuracy is achieved for the expected value of Vrm_{IS} 664. Those of skill in the art will appreciate that if the manufacturing tolerances permit, this calibration can be performed once to tool the product for manufacture of the current sensor assembly 400. If not, the burden resistor R_{B} 411 for each current sensor assembly could be laser trimmed as part of the manufacturing process.

This initial calibration essentially serves to pin the range of service current to the maximum magnitude of the desired output range of the sensed current output of the current sensor assembly 400. Those of skill in the art will appreciate that it can be any two points of the two ranges. For example, one could use 100 amps (i.e. halfway point of the range) and the expected value of 2.5 volts (halfway through the range of the sensed current output) as the calibration point, or any other value of the current and the expected magnitude that current should produce. Additional points of calibration could also be used to adjust the value of the burden resistor R_{B} 411 so that both all sets of points are within the required degree of accuracy. Thus, the smart meter will, (as with prior art current sensors), sample and convert magnitudes of the sensed current output Vrm_{IS} 664 and will convert that value to a service current magnitude I_{S} 13 based on the assumption that the ranges of Vrm_{IS} 664 and I_{S} 13 are directly proportional with one another over their respective ranges.

Those of skill in the art will appreciate, however, that while the current transformer 450 has a response that is most linear before saturation of the core, the transformer is not perfectly linear over that range, and that nonlinearity can be the source of additional inaccuracy that prevents achieving the required accuracy, notwithstanding performance of the initial calibration. Because of the broad range and large magnitudes of current that must be sensed for a given level of service for a current sensor to support electronic metering, nonlinear variations in transformer response can lead to deviations from what optimally would be a directly proportional output response for Vrm_{IS} 664 over its range. Thus, a second form of calibration can be performed whereby the known current can be swept over the entire range of current to be sensed for a given class of service, and the values of Vrm_{IS} 664 can be sampled and stored at fixed interval values of the known current sourced into the current sensor assembly 400 over the given range of service.

For example, the sourced known current can be swept over the given range of service current (e.g. from 0 to 200 amps), and an analog to digital converter (ADC) can be used to sample and digitize values of the output voltage Vrm_{IS} 664 for a constant step value of the known input current (e.g. 0.1 amps) resulting in 2000 pairs of digitized values for the known current and Vrm_{IS} 664, which can be stored as a calibration profile for the calibrated sensor assembly 400. These pairs of values can be stored in a reverse lookup table (e.g. that could be resident in the smart meter). When deployed in a smart meter application as illustrated in FIG. 6, as the RM current sensor assembly 400 senses the service current and produces its proportional magnitude over the output range of Vrm_{IS} 664 that is provided as input to the smart meter, those values can be digitized, and a closest match search can be run through the table. For each magnitude of Vrm_{IS} 664 sampled and digitized by an A/D converter of the smart meter, the stored known service current value associated with the closest match for each digitized sample will be returned as the digitized value of the sensed current I_{S} 13. Those of skill in the art will appreciate that additional accuracy can be achieved by reducing the incremental step of the sourced current input to increase the number of data pairs, or interpolation techniques could be used between the pairs of values.

It will be appreciated that if manufacturing tolerances are able to maintain the predetermined degree of accuracy for a given configuration of the current sensor assembly 400 for a given service (range of current), the first and/or second calibration steps could be performed just once for that configuration as a tooling step prior to mass production of the tooled configuration of the current sensor assembly. As long as the current sensor assemblies are meeting the required degree of accuracy over substantially the entire range of the service current notwithstanding cumulative manufacturing tolerances of the various components of the tooled configuration, all sensor assemblies 400 built with that configuration would be able to use the same calibration profile for the given range of service current. If the manufacturing tolerances do not permit use of the same tooled calibration profile to achieve the required degree of accuracy over the given range, then a calibration profile can be uniquely generated and associated with each current sensor assembly.

The digitized calibration profile data can be stored on any form of non-transitory memory associated with the SOCh 656b, FIG. 6 of the smart meter 656, FIG. 6 as a calibration profile look-up table. Those of skill in the art will appreciate that currently available smart meter designs already employ memory, as well as a processor that can be programmed to perform a closest match search memory look up operation. Thus, as service current is being monitored by RM current sensor assembly 400, it produces a continuous values at Vrm_{IS} 664 that is provided to the analog front end (AFE) 656a of smart meter 656. The AFE 656a samples, rectifies and converts the sampled values of Vrm_{IS} 664 into digital values. Those values are then provided to the SOCh 656b, which uses each of those digitized values as a match search input to the lookup table containing the calibration profile for the RM current sensor assembly 400. A search of the table is made for the closest match between digital samples of the sensed current output from the RM current sensor assembly to the calibrated sensed current output values of the profile. The stored value of the sourced known current associated with the best match for the sensed current output Vrm_{IS} 664 values is read out as the actual value of the sensed service current I_{S} 13 for that sample of the Vrm_{IS} 664 output. Thus, any variations caused by operating conditions of the sensor assembly 400 in the field are ignored in favor of values that the sensor should be producing as calibrated.

Those of skill in the art will further appreciate that prior art smart meters can also be employed to compensate for other factors that may affect accuracy of the sensed service current, such as temperature and altitude at an installed location. These factors will generally affect the values uniformly over the entire range. Thus, a transfer function could be created based on, for example, the ambient temperatures effect on the proportionality of the current sensor assembly, and this transfer function could be stored with the smart meter and used by the smart meter to transform the calibration profile as the smart meter senses changes in ambient temperature. These transfer functions could be created from calibration profiles generated from a current sensor assembly 400 as it is exposed to variations in the environmental parameters.

It will be appreciated that the level of calibration will depend upon the required degree of accuracy for a given application. Thus, the initial calibration of the ranges at one or a few points may only be required to achieve a required degree of accuracy. It may also be possible to achieve the required degree of accuracy by performing the full calibration over the given range and generating and using the calibration profile without the first calibration.

As previously discussed, the current I_{N} flowing in the neutral service wire (N 16b, FIGS. 1 and 2A-B) can also be sensed for purposes of determining whether ground faults exist that will lead to an imbalance between I_{S} and I_{N} resulting from the presence of a leakage current to ground such as I_{LK} 70. As previously discussed, the prior art suggests that monitoring for leakage current will require a large and therefore costly current transformer to sense current in the neutral service line, and an additional means to compare the current outputs and to amplify that sensed difference. Those of skill in the art will appreciate that the RM current measurement technique of the invention could be accomplished in a similar manner by using an RM current sensor assembly 400 for each service line and a differential amplifier to detect imbalances in the two currents. However, the RM approach can be further leveraged as described below to easily configure an RM differential current sensor assembly 500 of the invention that requires a single toroid to render the detection of leakage current at the metering level far more cost-effective. Moreover, this device can be used in place of prior art components currently deployed at the individual branch level.

In an embodiment of the invention as illustrated in FIG. 5, the RM current measuring technique can be leveraged to produce a small and integrated RM differential current sensor assembly 500. The RM current measurement technique of the invention enables the easy integration of two of the RM current sensor assemblies 400 into a differential current sensor assembly 500 of the invention that shares the same core as illustrated in FIG. 5. Thus, the differential current sensor of FIG. 5 can replace prior art current sensor 52 (including R_{SHUNT} 306 and operational amplifier 300), current transformer 54 (including toroid 304, burden resistor 303 and op amp 300) and differential amplifier 301.

The RM differential sensor assembly 500 of the invention in effect integrates or merges two RM current sensor assemblies (400_{S}, 400_{N} of FIG. 5) back to back (400, FIG. 4), which measure the current flowing in the S 16a and N 16b service lines respectively. The RM sensor assemblies 400_{S} and 400_{N} are integrated in that they share a single toroid 550, including core 510 and burden resistor R_{DIFF} 511. This physical integration is facilitated by the fact that the high-impedance conductors used to form secondary paths 408_{S}, 408_{N} of sensors assemblies 400_{S} and 400_{N} respectively are, for example: thin, flexible, insulated wires, or printed circuit board (PCB) traces (insulated from one another by occupying different interconnect levels of the PCB), that can be easily fed or routed (respectively) through the shared core 510 of toroid 550. While the high-impedance conductors forming secondary paths 408_{S}, 408_{N} could be attached directly to existing service lines S 16a and N 16b, those of skill in the art will appreciate that it is more practicable to manufacture RM differential sensor assembly 500 to be placed in series with the service lines through low impedance conductors 416a to 416a′ and 416b to 416′ to facilitate integration of the current sensing function into a smart meter assembly 618, FIG. 6 as a current sensor assembly 400, FIG. 6.

The current flowing in the I_{S} service line S 16a is divided into currents I_{MS} (flowing in the main path 406_{S} of the current divider of RM current sensor assembly 400_{S}) and I_{WS} (flowing in the secondary path 408_{S} of the RM sensor assembly 400_{S}). Likewise, the current I_{N} flowing in the neutral service line N 16b is divided into currents I_{MN} (flowing in the main path 406_{N} of the current divider of RM current sensor assembly 400_{N}) and I_{WS} (flowing in the secondary path 408_{N} of the RM sensor assembly 400_{N}). As previously discussed, I_{S} should be equal to I_{N} in the absence of any leakage current. Thus, so long as the current ratios of the current dividers of 400_{S} and 400_{N} are approximately equal (any difference can be calibrated out), I_{WS} and I_{WN} will be equal. In this case, there will be virtually zero differential current and Vrm_{DIFF} 665 will be zero volts. As the presence of leakage current (I_{LK} 70, FIG. 6A) increases in an electrical branch circuit 25, the differential output voltage Vrm_{DIFF} 665 increases proportionally to the increasing differential between the currents I_{S} and I_{N}.

For the single phase residential application, these conductors forming the secondary paths are arranged so that their respective currents I_{WS} and I_{WN} are fed or passed through the same core 510 in an anti-phase relationship with one another such that any difference or imbalance in the current flowing in those secondary paths will produce a magnetic flux that will generate a voltage Vrm_{DIFF} 665 across burden resistor R_{DIFF} 511 between output lines 565, 565′ that is proportional to the difference in currents. Those of skill in the art will appreciate that the symmetry of the RM differential amplifier renders Vrm_{DIFF} 665 more accurately than prior art solutions, as any non-linearity or other errors between the two sensed currents will tend to cancel each other out. Using a single core and a common (RM) method of current measurement inherently eliminates non-linearity and other variables common in prior art methodologies, including those resulting from the use of two different types of current sensor to measure the currents in S₁ 16 and N 16b as illustrated in FIGS. 2 and 3.

The parameters of the RM differential current sensor assembly 500 can be designed and calibrated in the same manner as described above for RM current sensor assembly 400. However, the RM differential sensor assembly should require no calibration provided that manufacturing tolerances are within the predetermined degree of accuracy required for detection of leakage currents. The accuracy for leakage current should be more relaxed than that required to meter power consumption. Thus, a tooled initial calibration to establish the same proportionality for each current may all that is required. Any remaining imbalance exists as an initial condition can be simply normalized when establishing any protection thresholds. It will be appreciated that even if the impedance ratios are not calibrated to produce identical proportionalities between the two common current dividers, any amount of initial imbalance can be normalized in creating protection threshold(s) established for indicating the presence of leakage current.

Those of skill in the art will appreciate that a plurality of threshold values of V_{DIFF} can be established by which to trigger increasingly more urgent actions related to the presence of leakage current that exceeds some tolerable level established by the threshold value of Vrm_{DIFF} 665. This can now be done at the service level by the smart meter 656 itself and can thus monitor for an overall cumulative leakage for the entire branch circuit 25. Multiple thresholds can be established, wherein reaching or exceeding a first threshold level can result in a warning indicator (e.g. a light, a sound, etc.), and messages can be sent to the user and the provider via the Internet 644 over network connection 642. Exceeding a highest threshold value could lead to an actual opening of the main breaker 22 of the branch circuit 25 electronically using a control signal (Trip_{MSTR} 617) generated in response thereto.

The RM sensor assembly 655 is therefore intended to be virtually drop-in replaceable for the prior art current sensor assembly 55, FIG. 2. Similar to the path shown in FIG. 2, the split-phase service line S 16a is provided as an input to smart meter assembly 618, which is passed through both RM Current Sensor assembly 400 and RM differential current sensor assembly 500, before emerging as S 16a′ to be coupled to the master circuit breaker 22 of service panel 20, FIG. 1. Neutral service line N 16b, 16b′ is likewise provided as a passthrough input and output through RM differential current sensor 500 as illustrated in FIG. 6. Thus, all of the prior art sensors of prior art sensor assembly 55, including all of the associated circuitry by which to amplify sensed current signals and to detect and amplify the difference between I_{S} 13 and I_{N} 15, can be replaced with one small and inexpensively manufactured RM current sensor assembly 400 and one small and inexpensively manufactured RM differential transformer/current sensor assembly 500.

It should be noted that voltage divider 609 to provide the voltage V_{S} across S 16a and N 16b lines is relatively unchanged other than possibly the values of the resistors. It should also be noted that the galvanic isolation interface 59 shown in the prior art smart meter 56 between the AFE 56a and the SoCh 56b in FIG. 2 is no longer required in the smart meter 656 of FIG. 6 because the RM current sensor assembly 400 provides the galvanic isolation the shunt resistor does not.

Thus, the method of manufacturing the RM differential current sensor 500 is not as complex as that for the RM current sensor assembly 400. The same considerations apply to configuring the circuit to achieve a target proportionality that reduces the size of the core 510 of the toroid, and reduces the current to be sensed to a range for which the differential current transformer 550 can operate over the substantially linear portion of its operating range, but because it operates on differential currents that will be quite small, this should be easier to achieve. An initial calibration of the output range over the given range of the service current for each divider may be desirable at tooling.

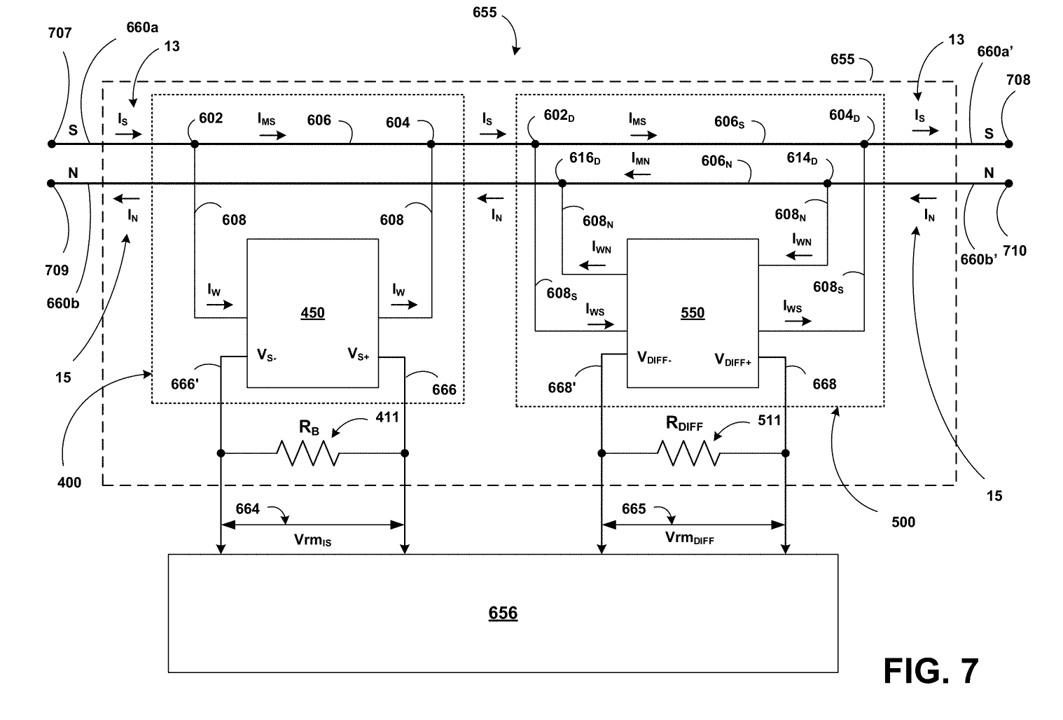

FIG. 7 illustrates a circuit block diagram of the RM sensor assembly 655, FIG. 6 without the voltage divider 609, which is largely the same as was described for the prior art. Those of skill in the art will appreciate that the toroidal current transformers 450 of the RM current sensor assemblies 400 and 550 of the RM differential current sensor assembly 500 are represented by general circuit blocks 400 and 500, and only the wired connections and burden sensors R_{B} 411 and R_{DIFF} 511 are shown for simplicity. RM sensor assembly 655 can be configured as a printed circuit board (PCB), to be conductively coupled in series with service line S 16a at edge connectors of the PCB at points 707, 708 through low impedance conductor 660a to 660a′. Likewise, RM sensor assembly 655 can be configured to be conductively coupled in series with service line N 16b at edge connectors of the PCB at points 709, 710 through low impedance conductor 660b to 660b′. The components of the RM sensor assembly 655 can be assembled on the printed circuit board PCB and all of the interconnect illustrated in FIG. 7 can be implemented as printed circuit board interconnect traces deposited on or below the surface of the PCB. Higher impedance conductors 608, 608_{N} and 608_{S} can be achieved as traces of higher resistive conductive elements such as resistors or even resistors in series with low impedance interconnect, or they can be flexible wires of higher impedance material that are insulated.

Those of skill in the art will appreciate that wires of higher resistance conductive material can be easily fed through their respective cores mounted on the PCB. However, the toroidal cores 410, 510 can also be partially embedded into the PC board, which would allow higher impedance traces to be routed through them. The secondary windings 409, 509 can be formed by wire hoops that can be coupled to traces on or within the PCB. It will be appreciated that there may be a number of ways that the RM current sensors assemblies 400, 500 of the invention can be physically implemented, but one important aspect of any such implementation is that the relatively high-impedance of the conductor used to form the secondary path(s) 408, 408_{S}, 408_{N} is (are) capable of being physically routable through the cores 410, 510 of the toroidal current sensors 450, 550. The conductors forming the secondary paths 408, 408_{S}, 408_{N} should be insulated or isolated to avoid inadvertent contact with other parts of the various assemblies.

The RM current sensor assembly 400, used for sensing the service current I_{S} 13 is magnetically coupled to higher impedance wire (or PCB trace) 608, which is conductively coupled to points 602, 604 to form the secondary path in parallel with main path 606 along conductor 660a, 660a′ to forth the current divider. Toroidal current transformer 450 is magnetically coupled to the secondary path formed by higher impedance conductor 608 passing as a winding through toroid 410. RM current sensor assembly 400, as described above, produces output Vrm_{IS} 664 across the burden resistor R_{B} 411 that is provided to smart current meter 656 by lines 666 and 666′. Vrm_{IS} 664 has a proportionality to the current I_{S} 13 that is partially established based on the impedance ratio between conductor 660a to 660a′ between interconnect nodes 602, 604 and wire 608, which defines the current ratio between the current I_{W} flowing in wire 608 and the current I_{MS} flowing in the main path 606, formed between the two attachment points 602, 604 along low impedance conductor 660a to 660a′. The proportionality is further partially established based on the turns ratio of the toroidal current transformer 450 and the value of the burden resistor R_{B} 411. Burden resistor R_{B} 411 can be implemented as a standard component mounted on the PCB once tooled, or it can be implemented as an interconnect resistive element on the PCB surface, that can be laser trimmed for additional accuracy.

Likewise, RM sensor 400_{S}, which is half of the RM differential current sensor assembly 500, FIG. 5, is also magnetically coupled to a secondary path formed by a second higher impedance conductor 608_{S} conductively coupled to service line S 16 through low impedance conductor 660a to 660a′. Higher impedance wire (or PCB trace) 608_{S} is conductively coupled to points 602, 604, to form the secondary path of the current divider in parallel with main path 606 along conductor 660a, 660a′. The fractional current flowing in wire 608_{S} is proportional to the current flowing in return (i.e. neutral) service line N 16a based on the ratio between the current I_{WS} flowing in wire 608_{S} and the current I_{MS} flowing in the main path 606_{S}, formed between the two points 602D, 604D along line S 16a. Toroidal differential current transformer 550 is magnetically coupled to the secondary path formed by higher impedance conductor 608_{S} passing as a winding through toroid 510.

RM sensor assembly 400_{N}, which is the second half of RM differential sensor assembly 500 (FIG. 5) is magnetically coupled to a secondary path formed by a third higher impedance conductor 608_{N}, which is conductively coupled to the return current service line N 16b, at circuit nodes 614_{D}, 616_{D}. Differential current transformer 550 is magnetically coupled to the secondary path formed by higher impedance conductor 608_{N} by passing it as a winding through toroid 510. I_{WS} and I_{WN} are fed or passed through core 510 in an anti-phase relationship with one another such that any difference or imbalance in the current flowing in those secondary paths will produce a magnetic flux that will generate a voltage Vrm_{DIFF} 665 across burden resistor R_{DIFF} 511 between output lines 565, 565′ that is proportional to the difference in currents.

RM differential current sensor assembly 500, as described above, produces output Vrm_{DIFF} 665 is provided to smart current meter 656 by lines 668 and 668′. Vrm_{DIFF} 665 has a proportionality to the current I_{N} 15 that is partially established based on the impedance ratios of the two current dividers, as well as the turns ratio of the toroidal differential current transformer 550 and the value of the burden resistor R_{DIFF} 511. As previously discussed, the precise ratios for each of the fractional currents will not have to match, as any initial imbalance between the currents in the absence of leakage can be normalized when establishing the value of the determined protection thresholds for leakage. However, it would not be difficult to subject the two current dividers to an initial calibration that calibrates the target proportionality for each current divider plus transformer to be substantially the same as previously described.

Thus, if the magnitudes of currents the service currents I_{S} and I_{N} are equal (and the current ratio of the two sensor assemblies 400_{S} and 400_{N} are substantially equal), the toroid will detect substantially zero differential current when no leakage is present. If leakage current (I_{LK} 70, FIGS. 2A, B) increases, I_{N} will decrease, and the imbalance will be reflected in the voltage across R_{DIFF} 511 (FIG. 5). Those of skill in the art will appreciate that a comparator circuit can be used to compare the voltage across R_{DIFF} 511, either in analog or digitized numerical values, to determine if a predetermined leakage threshold has been exceeded.

The metering of power consumption should be as accurate as economically feasible, to the benefit of both the consumer and the supplier. As previously discussed, the challenge for maintaining this accuracy over a broad range of high magnitude current is that the current sensor used to measure the current drawn by the consumer in a power metering application must operate substantially linearly over a very broad range of current. For a typical residential service, the current can range in magnitude from just above 0 amps to 200 amps. The upper range for larger residences and buildings can be much higher. Industrial applications are typically three phases and the magnitude of the upper range can (and likely will be) higher still. A high level of accuracy is also important for the measurement of differential currents in detecting ground faults as previously discussed, as the magnitude of differential currents are the difference between two values, and thus any error becomes magnified. Obtaining linearity with current toroid transformers requires the use of core materials such as nickel/iron and constraining their operation to the most linear part of the magnetizing BH curve.

FIG. 8A shows a B-H curve 802 and illustrates the linear portion of a typical toroidal current transformer's response. Those of skill in the art will recognize that there is a difference in the response depending upon the direction of the current. This produces a magnetic hysteresis as well as nonlinear behavior at the upper and lower portions of the curve. FIG. 8B illustrates an average of the response 804 between the two directions of current flow, and the approximate linear range 806. Those of skill in the art will recognize that the hysteresis can be mitigated by using an appropriate material for the core 410 as previously discussed. While calibrating a single RM current sensor assembly 400 over the full range of current as previously disclosed, will improve accuracy over prior art implementations, this calibration cannot eliminate the inherent non-linear behavior of the RM current sensor assembly 400 over the non-linear portion of its transformer curve (i.e. at the top and bottom of the current range).

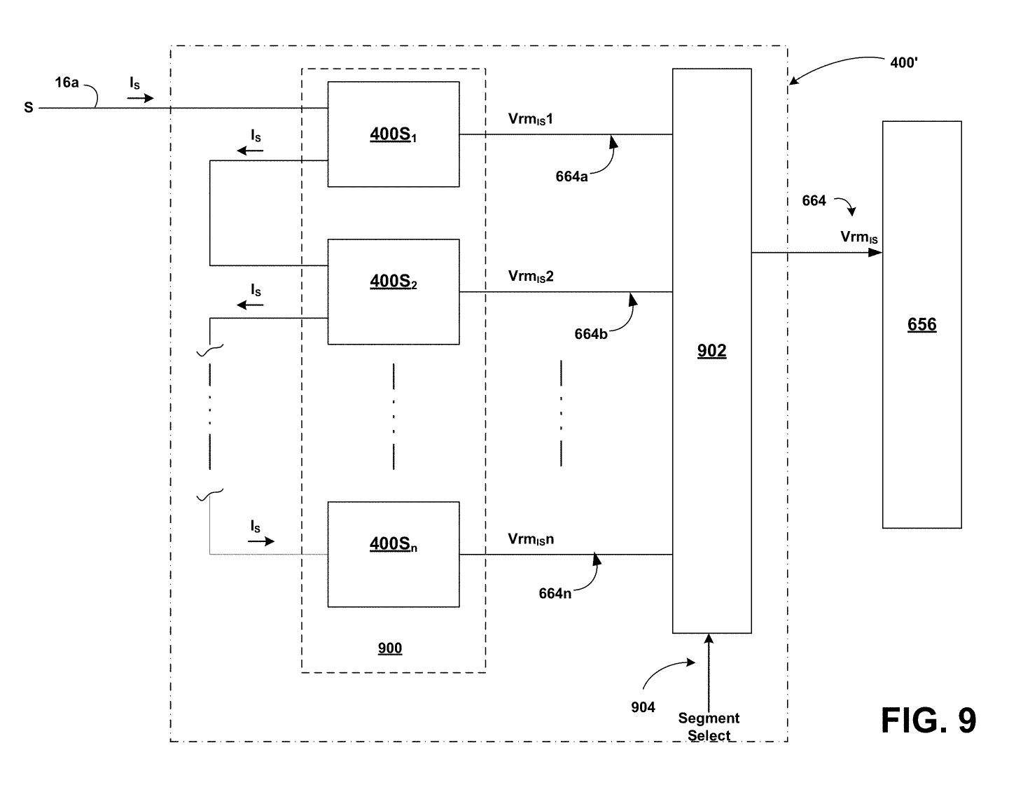

As was previously discussed above for an implementation with a single current sensor to cover the entire range, the goal is to establish a target proportionality between the service current I_{S} 13 to the magnitude of the sensed current output should cause the current sensor to operate substantially within its linear range of operation. If the range is wide enough, or the desired accuracy tight enough, it may be desirable to divide the range of current into segments and assign a separate RM current sensor assembly 400 uniquely configured to sense each segment. FIG. 9 illustrates an alternate embodiment 400′ of RM current sensor assembly 400 of FIG. 6, whereby a bank 900 of two or more of the RM current sensor assemblies 400S₁₋ₙ can each be dedicated to provide the sensed service current output Vrm_{IS} for a unique segment or subrange of the overall current range. Each RM current sensor assembly 400S can be uniquely configured with a proportionality (as discussed previously) to ensure that each sensor assembly will operate so that its assigned segment of the current range coincides with the most linear part of its B-H curve.

Put another way, the full range of current to be sensed can be divided into segments, and the proportionalities for each RM current sensor assembly 400 can be optimized to provide the most linear operation over each segment. Those of skill in the art will appreciate that it would be impossible to guarantee ideal operation for all segments down to the lowest value of the current range, but there will be some value of I_{S} 13 at which some nonlinear operation can be tolerated. As previously described, the number of windings, size of the core of the toroidal current transformer 450, as well as the high impedance path of the wire 408 forming the secondary path, can be configured to establish a unique operational proportionality for each of the RM sensor assemblies 400S₁ to 400Sₙ. This includes their calibration as previously described, but now only cover the range of its assigned segment within the total current range of service current to be sensed.

Multiplexer 902 can be used to represent the function by which a selection is made to provide one of the n current sensor outputs Vrm_{IS1} to Vrm_{IS}. (664a to 664n) to the AFE 656a of smart meter 656 at a time. This is preferable because most if not all currently available smart meter AFEs 656a have only one ADC by which to digitize the output of each sensor assembly 400. The selection can be made based on the Segment Select input 904 to multiplexer 902 that chooses the Vrm_{IS} 664 output from the RM current sensor assembly 400S that is assigned to that segment of the range of magnitude in which service current I_{S} 13 currently resides. Those of skill in the art will recognize that there are many ways to provide this selection function. For example, a plurality of comparators for each segment can be used to detect when the amplitude of service current I_{S} 13 falls with the current range that defines a particular segment, and the outputs of the comparators can be used to provide a unique set of n bits that can be decoded to select the Vrm_{IS} output 664 for the appropriate segment. This permits the smart meter to receive and process only one input for Vrm_{IS} 664.

FIG. 8C shows such an example of one possible segmentation profile. If a smart meter 856 is to meter current for a service that provides 0-400 amps, a first RM current sensor assembly 400S₁ could be configured to operate most linearly over a range of 40 to 400 amps (See 808a, FIG. 8C). A second RM sensor assembly 400S₂ could be configured to operate most linearly over a range of 4 to 40 amps (See 808b, FIG. 8C with some overlap between the two ranges), and a third RM sensor assembly of the invention 400S₃ (See 808c, FIG. 8C) could be configured to most linearly operate over a range of from 0.4 to 4 amps. This means that each segment of the range represents a factor of ten between the low and high values of the range.

Those of skill in the art will appreciate that as a practical matter, it is unlikely that a consumer would draw much less than 4 amps from any level of service, and that for most applications only two segments of the range likely would be required to substantially realize the benefit of the extended linearity offered. The three segment example above is shown merely to demonstrate that the implementation of a segmented current range theoretically can be extended to as many segments as is practicable. Because the RM current sensor assembly 400, FIG. 4 is so inexpensive and simple to employ, the cost is not a factor in the number of sensors that can be used practicably.

It will be appreciated that to take full advantage of the benefits of the RM sensor assembly 655 as set forth herein, some alterations in current smart meter designs may be required. For example, interface 659 no longer requires galvanic isolation techniques because all of the RM current sensor assemblies 400, 550 are electrically isolated from the line voltage by their magnetic coupling to the secondary paths of the current dividers. Such circuitry can now be eliminated. In addition, to take advantage of the full calibration of a single RM current sensor assembly 400 over the full range of service current, a means for providing a non-transient storage of the calibration profile must be stored and accessed by smart meter SoCh 659b to establish calibrated magnitude values for I_{S} 13.

If individual calibration is desired, taking advantage of segmentation of the range to improve accuracy may require that the smart meter SoCh 659b be able to store and retrieve calibrated values from calibration profiles unique to each RM current sensor assembly 400S₁ to 400Sₙ assigned to segments of the current range. This would require endpoint values defining each of the segments be stored and used to select from which of the calibration profiles to retrieve calibrated values of I_{S} 13. This would likely be an extreme application requiring very high accuracy.

Embodiments of the current sensing technique of the invention are able to provide higher accuracy regarding the frequency content of the sensed current over a wider bandwidth, and at a much lower cost and smaller size than prior art sensors. Put another way, the ratio metric current measurement technique of the invention maintains the harmonic content of the current signal over a wider bandwidth, but without the commensurate increase in cost and/or complexity associated with prior art techniques such as current transformers. This advantage of the invention facilitates a significantly more accurate harmonic (signature) analysis of the current drawn from the service by the consumer's electric branch circuit, but at a significantly lower cost and smaller size. Thus, valuable signature analysis of the consumer's current can be enabled on a mass scale.

For example, harmonic signature analysis of the consumer's current at the point of service can be performed to detect arc faults manifesting as series and parallel leakage currents within the electric branch circuit and surrounding insulation. See related US Patent Application No. A smart meter employing the RM current sensor assemblies of the invention can cost-effectively monitor the operational health of insulation in the wiring to detect the potential for, and ultimately to pre-empt, building fires. The performance of various load components such as motors for air conditioning, large appliances, and industrial installations can also be monitored using this signature analysis to determine declining performance of such devices to trigger their repair or replacement. It should be noted that when signature analysis is only concerned with analyzing the current in the frequency domain, one could employ an additional RM current sensor assembly 400 that is dedicated to providing a signal for signature analysis. In this case. no calibration would be required because the accurate derivation of the proportionality is not important when the magnitude of the current is not considered.

Those of skill in the art will appreciate that the RM differential current sensor assembly 500 of FIG. 5 can be adapted to polyphase applications as well. For example, for a three-phase power service there will be three merged RM current sensor assemblies 400, one for each phase. The conductors forming their respective secondary paths will be fed through a common toroid and will be in a balanced phasic relationship where each phase is 120 degrees out of phase with the others. Once again, if all currents are equal in the three secondary path conductors, the vectors of the three phases will be balanced and there will be no flux in the core. Should current in one or more of the secondary path conductors become imbalanced due to leakage currents, the flux generated as a result of the imbalance will result in an output Vrm_{DIFF} 665 across resistor R_{DIFF} 511 between output lines 656, 656′ that is proportional to the imbalance.

Finally, it will be appreciated by those of skill in the art that the RM current sensor assembly 400 and the RM differential current sensor assemblies 500 can be applied to any application that must provide current sensing and monitoring functions, and particularly over broad ranges of high magnitude currents. The calibrations disclosed herein can be applied in any combination as is most expedient and cost optimal to achieve the requisite predetermined accuracy required for the application. Moreover, based on the several calibration techniques that are available to render the RM current sensor assemblies 400, 500 more accurate, any combination of those proposed calibration techniques can be combined to improve accuracy in the most cost effective manner. This level of accuracy can be achieved with the highly cost effective use of PCB technology, small toroidal current sensors and the elimination of unnecessary galvanic isolation circuits that can lead to full integration of the current sensing functions into a fully integrated smart meter assembly 618 itself as illustrated in FIG. 6. And finally, it will lead replacement of the shunt resistor, which cumulatively leads to enormous saving of energy otherwise dissipated by the shunt resistor.

What is claimed is:

1. A process for the manufacture of a ratio metric (RM) current sensor assembly that senses service current drawn by an electrical branch circuit from an electrical service with a predetermined degree of accuracy, the electrical service providing a predetermined range of service current, said method comprising:
providing a current divider between a low impedance conductor and a relatively high impedance conductor, the low impedance conductor configured to be coupled in series with a service line carrying the service current;
providing a current transformer having a toroidal core magnetically coupled to the higher impedance conductor of the current divider;
establishing a target proportionality between the predetermined range of the service current and a sensed current output voltage of the RM current sensor assembly, the sensed current output configured to be a voltage produced across a burden resistor coupled to a secondary of the current transformer, the target proportionality establishing a desired range for the sensed current output that falls substantially within the more linear range of the current transformer;
configuring the RM current sensor assembly to achieve the target proportionality based on at least an estimate of the impedance ratio of the current divider, the turns ratio of the current transformer and burden resistor value, the configured current sensor having an actual proportionality; and
if the actual proportionality is not within the predetermined degree of accuracy substantially over the predetermined range of service current, performing a first calibration whereby at least the burden resistor is adjusted in value so that for at least one magnitude of the service current range, the sensed current output is equal to an expected magnitude within the predetermined degree of accuracy.

2. The process of claim 1, wherein the at least one magnitude of the service current is the maximum magnitude of the predetermined range of the service current, and the expected value of the sensed current output equals the maximum magnitude of the desired range of the sensed current output.

3. The process of claim 1, wherein the first calibration includes:
sourcing a known current of the at least one magnitude of the service current range into the low impedance conductor of the RM current sensor assembly, and
adjusting the burden resistor value until the sensed current output voltage equals the expected magnitude.

4. The process of claim 3, wherein the adjusting the burden resistor value is performed by laser trimming the burden resistor once for tooling the RM current sensor assembly for manufacturing.

5. The process of claim 3, wherein the adjusting the burden resistor value is performed by laser trimming the burden resistor after the RM current sensor assembly is manufactured.

6. The process of claim 2, wherein at least one of: said providing a current divider, said providing a current transformer, said establishing a target proportionality, said configuring the RM current sensor assembly, and said performing a first calibration is performed using a computer simulation prior to manufacturing the RM current sensor assembly.

7. A ratio metric (RM) current sensor assembly that senses service current drawn by an electrical branch circuit from an electrical service with a predetermined degree of accuracy, the electrical service providing a predetermined range of service current, said RM current sensor assembly manufactured by a process comprising:
providing a current divider between a low impedance conductor and a relatively high impedance conductor, the low impedance conductor configured to be coupled in series with a service line carrying the service current;
providing a current transformer having a toroidal core magnetically coupled to the higher impedance conductor of the current divider;
establishing a target proportionality between the predetermined range of the service current and a sensed current output voltage of the RM current sensor assembly, the sensed current output configured to be a voltage produced across a burden resistor coupled to a secondary of the current transformer, the target proportionality establishing a desired range for the sensed current output that falls substantially within the linear range of the current transformer;
configuring the RM current sensor assembly to achieve the target proportionality based on at least an estimate of the impedance ratio of the current divider, the turns ratio of the current transformer and burden resistor value, the configured RM current sensor assembly having an actual proportionality; and
if upon configuration the actual proportionality is not within the predetermined degree of accuracy substantially over the predetermined range of service current, performing a first calibration whereby at least the burden resistor is adjusted in value so that for at least one magnitude of the service current range, the sensed current output is equal to an expected magnitude within the predetermined degree of accuracy.

8. The RM current sensor assembly of claim 7, wherein the first calibration includes:
sourcing a known current of the at least one magnitude of the service current range into the low impedance conductor of the RM current sensor assembly, and
adjusting the burden resistor value until the sensed current output voltage equals the expected magnitude.

9. The RM current sensor assembly of claim 8, wherein the adjusting the burden resistor value is performed by laser trimming the burden resistor once for tooling the RM current sensor assembly for manufacturing.

10. The RM current sensor assembly of claim 7, wherein at least one of: the providing a current divider, the providing a current transformer, the establishing a target proportionality, the configuring the RM current sensor assembly, and the performing a first calibration is performed using a computer simulation prior to manufacturing the RM current sensor assembly.

11. A ratio metric (RM) sensor assembly for sensing a service current being drawn from an electrical service through a service line by an electric branch circuit to support electronic metering of the electrical energy consumed thereby, the electrical service being configured to provide a predetermined range of current magnitude at a fundamental frequency, the RM sensor assembly comprising:
one or more RM current sensor assemblies comprising:
a current divider formed of:
a low impedance conductor, the low impedance conductor configured to be conductively coupled in series with a service line carrying the service current to the electrical branch, and
a higher impedance conductor coupled at two points along the lower impedance conductor; and
a current transformer including:
a toroidal core through which the higher impedance conductor is fed as a primary winding; and
a secondary formed of one or more windings about the core and coupled to a burden resistor that is coupled to the secondary,
wherein the RM current sensor assembly is configured to produce a sensed current output across the burden resistor, the sensed current output having a predetermined operational range of magnitude that is proportionally related to the sensed service current over the predetermined operational range of the service current, and
wherein the burden resistor of the RM current sensor assembly is configured to have a value that sufficiently compensates for inaccuracies in at least the impedance ratio of the current divider to ensure that the sensed current output is within the predetermined degree of accuracy over the predetermined operational range of the sensed current output.

12. The RM sensor assembly of claim 11, wherein the burden resistor of the RM current sensor assembly is configured to have a value that sufficiently compensates for inaccuracies in at least the impedance ratio of the current divider to ensure that the sensed current output is within the predetermined degree of accuracy over the predetermined operational range of the sensed current output.

13. The RM current sensor assembly of claim 12, wherein:
the predetermined range of the service current is apportioned into one or more contiguous segments, and each of the one or more RM current sensor assemblies is assigned to sense current for one of the one or more segments; and
the proportionality for each of the assigned RM current sensor assemblies is configured such that it operates over a most linear portion of its operational curve when the magnitude of the service current being drawn through the service line falls within the segment to which it is assigned.

14. The RM current sensor assembly of claim 13, further comprising a multiplexor configured to:
select the sensed current output of the one of the one or more RM current sensor assemblies assigned to the segment within which the magnitude of the service current presently resides; and
to provide the selected output to a smart energy meter.

15. The ratio metric (RM) sensor assembly of claim 11, wherein each of the one or more current sensor assemblies are associated with a calibration profile, the calibration profile including a plurality of pairs of calibration values generated by:
sourcing a known AC current of the fundamental frequency into a calibration RM current sensor assembly that has the same configuration as the at least one RM current sensor assembly, the sourced current being swept in magnitude from the lowest to the highest magnitude of the predetermined range of the service current, and
for each one of a plurality of specified magnitudes of the known AC current, storing in a non-transient memory a pair of digitized values representing the specified magnitude of the known AC current and the sensed current output generated by the specified magnitude of the known AC current.

16. The RM sensor assembly of claim 11, wherein the one or more RM current sensor assemblies are calibrated using the calibration profile by performing a best match between the sensed current output values of the calibration profile and periodic digitized samples of the sensed current output magnitude produced by the RM current sensor during operation, and substituting the known AC current magnitude associated with the best matched sensed current output as the sensed magnitude for the service current for each of the digitized samples.

17. The RM sensor assembly of claim 11, further comprising a differential current sensor assembly including:
a first current divider formed of a low impedance conductor configured to be coupled in series with the service line, and a first higher impedance conductor coupled at two points along the lower impedance conductor;
a second current divider formed of a low impedance conductor configured to be coupled in series with a neutral line by which current is returned to the service, and a second higher impedance conductor coupled at two points along the lower impedance conductor; and
a differential current transformer including:
a toroidal core through which the first and second higher impedance conductors are fed as primary windings; and
a secondary formed of one or more windings about the core and coupled to a burden resistor that is coupled to the secondary,
wherein the RM current sensor assembly is configured to produce a sensed differential current output across the burden resistor, the sensed differential current output indicating a degree of imbalance between the current flowing in the service line and current flowing in the neutral line indicating the presence of leakage current to ground being present in the electric branch circuit.

18. A ratio metric (RM) differential current sensor assembly for detecting leakage current to ground present in an electric branch circuit drawing service current from an electrical service, the RM differential current sensor assembly including:
a first current divider formed of:
a first low impedance conductor configured to be conductively coupled in series with a service line carrying the service current to the electrical branch circuit, and a first higher impedance conductor coupled at two points along the lower impedance conductor;
a second current divider formed of:
a second low impedance conductor configured to be conductively coupled in series with a neutral service line carrying return current back to the service, and
a second higher impedance conductor coupled at two points along the second lower impedance conductor; and
a differential current transformer including:
a toroidal core through which the first and second higher impedance conductors are fed as primary windings; and
a secondary formed of one or more windings about the core and coupled to a burden resistor that is coupled to the secondary,
wherein the RM differential current sensor assembly is configured to produce a sensed differential current output across the burden resistor, the sensed differential current output indicating a degree of imbalance between the current flowing in the service line and current flowing in the neutral line indicating the presence of leakage current to ground being present in the electric branch circuit.

19. The RM differential current sensor assembly of claim 18, further including a comparator for generating an active signal to indicate that the degree of imbalance has exceeded a predetermined protection threshold value of the sensed differential current output, the active signal configured to send an alert over a network to a provider of the service.

20. The RM differential current sensor assembly of claim 18, wherein any initial imbalance between the currents caused by differences in the proportionality of at least the first and second current divider's can be offset from the protection threshold value.
